(19) United States
(12) Patent Application Publication
(10) Pub. No.: US 2026/0279468 A1
(43) Pub. Date: Sep. 17, 2026

(54) THRESHOLD VOLTAGE TRACKING TECHNIQUES FOR MEMORY DEVICES

(71) Applicant: Sandisk Technologies, Inc., Milpitas, CA (US)

(72) Inventors: Albert Chen, Milpitas, CA (US); Jiahui Yuan, Fremont, CA (US); Xiang Yang, Santa Clara, CA (US)

(21) Appl. No.: 19/080,065

(22) Filed: Mar. 14, 2025

(51) Int. Cl. G11C 16/34; G11C 16/12; G11C 16/26

(52) U.S. Cl. CPC G11C 16/3404; G11C 16/12; G11C 16/26

(57) ABSTRACT

A memory apparatus includes memory cells each connected to one of a plurality of word lines and disposed in memory holes and configured to retain a threshold voltage corresponding to data states. A control means is configured to detect a valley point between distributions of the threshold voltage of two of the data states for a group of the memory cells in a threshold voltage tracking operation. The control means is also configured to determine whether the valley point is between a first identified one of the data states and a second identified one of the data states or between the second identified one of the data states and a third identified one of the data states and set an optimal read level for one of the data states based on a count of the memory cells associated with the valley point.

### FIELD

This application relates to non-volatile memory apparatuses and the operation of non-volatile memory apparatuses.

### BACKGROUND

This section provides background information related to the technology associated with the present disclosure and, as such, is not necessarily prior art.

Semiconductor memory is widely used in various electronic devices, such as cellular telephones, digital cameras, personal digital assistants, medical electronics, mobile computing devices, servers, solid state drives, non-mobile computing devices and other devices. Semiconductor memory may comprise non-volatile memory or volatile memory. A non-volatile memory allows information to be stored and retained even when the non-volatile memory is not connected to a source of power, e.g., a battery.

NAND memory devices include a chip with a plurality of memory blocks, each of which includes an array of memory cells arranged in a plurality of word lines. The memory cells can be programmed to any of a plurality of data states that are associated with different threshold voltage Vt ranges. Data in the memory cells is read by applying reference voltages associated with the data states to a selected one of the word lines and comparing the threshold voltages of the memory cells to the reference voltages. In certain conditions, such as when a memory device sits idle for a long period of time, the threshold voltages Vt of the memory cells can shift. This can lead to failed bits if the read voltages are not adjusted to account for the shifts. Some techniques that adjust or optimize the read voltages are either time consuming or are not reliable.

### SUMMARY

This section provides a general summary of the present disclosure and is not a comprehensive disclosure of its full scope or all of its features and advantages.

An object of the present disclosure is to provide a memory apparatus and a method of operation of the memory apparatus that address and overcome shortcomings described herein.

Accordingly, it is an aspect of the present disclosure to provide a memory apparatus including memory cells each connected to one of a plurality of word lines. The memory cells are disposed in memory holes and configured to retain a threshold voltage corresponding to one of a plurality of data states. The memory apparatus also includes a control means configured to detect a valley point between distributions of the threshold voltage of two of the plurality of data states for a group of the memory cells in a threshold voltage tracking operation. The control means is also configured to determine whether the valley point is between a first identified one of the plurality of data states and a second identified one of the plurality of data states or between the second identified one of the plurality of data states and a third identified one of the plurality of data states and set an optimal read level for one of the plurality of data states based on a count of the memory cells associated with the valley point.

According to another aspect of the disclosure, a controller in communication with a memory apparatus is also provided. The memory apparatus includes memory cells each connected to one of a plurality of word lines. The memory cells are disposed in memory holes and are configured to retain a threshold voltage corresponding to one of a plurality of data states. The controller is configured to instruct the memory apparatus to detect a valley point between distributions of the threshold voltage of two of the plurality of data states for a group of the memory cells in a threshold voltage tracking operation. The controller is also configured to instruct the memory apparatus to determine whether the valley point is between a first identified one of the plurality of data states and a second identified one of the plurality of data states or between the second identified one of the plurality of data states and a third identified one of the plurality of data states and set an optimal read level for one of the plurality of data states based on a count of the memory cells associated with the valley point.

According to an additional aspect of the disclosure, a method of operating a memory apparatus is provided. The memory apparatus includes memory cells each connected to one of a plurality of word lines. The memory cells are disposed in memory holes and configured to retain a threshold voltage corresponding to one of a plurality of data states. The method includes the step of detecting a valley point between distributions of the threshold voltage of two of the plurality of data states for a group of the memory cells in a threshold voltage tracking operation. The method also includes the step of determining whether the valley point is between a first identified one of the plurality of data states and a second identified one of the plurality of data states or between the second identified one of the plurality of data states and a third identified one of the plurality of data states and setting an optimal read level for one of the plurality of data states based on a count of the memory cells associated with the valley point.

Further areas of applicability will become apparent from the description provided herein. The description and specific examples in this summary are intended for purposes of illustration only and are not intended to limit the scope of the present disclosure.

### DRAWINGS

For a detailed description of example embodiments, reference will now be made to the accompanying drawings in which:

FIG. 1A is a block diagram of an example memory device according to aspects of the disclosure;

FIG. 1B is a block diagram of an example control circuit according to aspects of the disclosure;

FIG. 2 depicts blocks of memory cells in an example two-dimensional configuration of the memory array of FIG. 1A according to aspects of the disclosure;

FIG. 3A and FIG. 3B depict cross-sectional views of example floating gate memory cells in NAND strings according to aspects of the disclosure;

FIG. 4A and FIG. 4B depict cross-sectional views of example charge-trapping memory cells in NAND strings according to aspects of the disclosure;

FIG. 5 depicts an example block diagram of the sense block SB1 of FIG. 1A according to aspects of the disclosure;

FIG. 6A is a perspective view of a set of blocks in an example three-dimensional configuration of the memory array of FIG. 1A according to aspects of the disclosure;

FIG. 6B depicts an example cross-sectional view of a portion of one of the blocks of FIG. 6A according to aspects of the disclosure;

FIG. 6C depicts a plot of memory hole diameter in the stack of FIG. 6B according to aspects of the disclosure;

FIG. 6D depicts a close-up view of region 622 of the stack of FIG. 6B according to aspects of the disclosure;

FIG. 7A depicts a top view of an example word line layer WL0 of the stack of FIG. 6B according to aspects of the disclosure;

FIG. 7B depicts a top view of an example top dielectric layer DL116 of the stack of FIG. 6B according to aspects of the disclosure;

FIG. 8 depicts a threshold voltage distribution of a page of memory cells programmed to three bits per memory cell (TLC) according to aspects of the disclosure;

FIG. 9 is a schematic view illustrating the voltages applied to a memory block during an exemplary sensing operation, such as verify or read according to aspects of the disclosure;

FIG. 10 is a waveform of a valley search or threshold voltage Vt tracking operation according to aspects of the disclosure;

FIG. 11 is a plot of threshold voltage distributions for two adjacent data states and illustrates a specific valley search scan or threshold voltage Vt tracking method according to aspects of the disclosure;

FIG. 12 shows plots of failure bit count (FBC) versus starting DAC with the maximum stair number equal to fourteen according to aspects of the disclosure;

FIG. 13 shows plots of threshold voltage distributions for two adjacent data states for fresh (PD) memory cells and after long data retention (long DR) and illustrates how the maximum stair number affects the search range according to aspects of the disclosure;

FIG. 14 is a plot of threshold voltage distributions of memory cells programmed to different data states for fresh (PD case) memory cells and shows different shifts of the read levels after data retention (DR) depending on the data state according to aspects of the disclosure;

FIG. 15 shows plots of threshold voltage distributions for three adjacent data states for fresh (PD) memory cells accounting for maximum temperature variations (TempX) and after long data retention (maximum DR) according to aspects of the disclosure;

FIG. 16 is a plot of threshold voltage distributions of memory cells programmed to different data states for fresh (PD) memory cells and for the memory cells after data retention (DR) according to aspects of the disclosure;

FIG. 17 shows plots of threshold voltage distributions for three adjacent data states for fresh (PD) memory cells accounting for maximum temperature variations (TempX) and after long data retention (maximum DR) and illustrates a predetermined read level according to aspects of the disclosure;

FIG. 18 shows plots of threshold voltage distributions for four adjacent data states for fresh (PD) memory cells accounting for maximum temperature variations (TempX) and after long data retention (maximum DR) and illustrates another predetermined read level according to aspects of the disclosure; and

FIG. 19 illustrates steps of a method of operating a memory apparatus according to aspects of the disclosure.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following description, details are set forth to provide an understanding of the present disclosure. In some instances, certain circuits, structures and techniques have not been described or shown in detail in order not to obscure the disclosure.

In general, the present disclosure relates to non-volatile memory apparatuses of the type well-suited for use in many applications. The non-volatile memory apparatus and associated methods of forming of this disclosure will be described in conjunction with one or more example embodiments. However, the specific example embodiments disclosed are merely provided to describe the inventive concepts, features, advantages and objectives with sufficient clarity to permit those skilled in this art to understand and practice the disclosure. Specifically, the example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

A programming operation for a set of memory cells of a memory device typically involves applying a series of program voltages to the memory cells after the memory cells are provided in an erased state. Each program voltage is provided in a program loop, also referred to as a program-verify iteration. For example, the program voltage may be applied to a word line which is connected to control gates of the memory cells. In one approach, incremental step pulse programming is performed, where the program voltage is increased by a step size in each program loop. Verify operations may be performed after each program voltage to determine whether the memory cells have completed programming. When programming is completed for a memory cell, it can be locked out from further programming while programming continues for other memory cells in subsequent program loops.

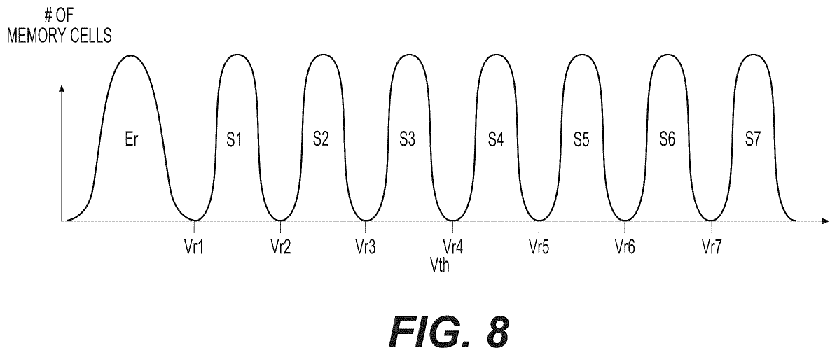

Each memory cell may be associated with a data state according to write data in a program command. Based on its data state, a memory cell will either remain in the erased state or be programmed to a data state (a programmed data state) different from the erased state. For example, in a one-bit per cell memory device (single-level cell (SLC)), there are two data states including the erased state and one higher data state. In a two-bit per cell memory device (multi-level cell (MLC)), there are four data states including the erased state and three higher data states referred to as the A, B and C data states. In a three-bit per cell memory device (triple-level cell (TLC)), there are eight data states including the erased state (Er) and seven higher data states referred to as the A or S1, B or S2, C of S3, D or S4, E or S5, For S6 and G or S7 data states (see FIG. 8). In a four-bit per cell memory device (quad-level cell (QLC)), there are sixteen data states including the erased state and fifteen higher data states referred to as the Er, 1, 2, 3, 4, 5, 6, 7, 8, 9, A, B, C, D, E and F data states. Each memory cell may store a data state (e.g., a binary value) and is programmed to a threshold voltage state corresponding to the data state. Each state represents a different value and is assigned a voltage window including a range of possible threshold voltages.

When a program command is issued, the write data is stored in latches associated with the memory cells. During programming, the latches of a memory cell can be read to determine the data state to which the cell is to be programmed. Each programmed data state is associated with a verify voltage such that a memory cell with a given data state is considered to have completed programming when a sensing operation determines its threshold voltage (Vth) is above the associated verify voltage. A sensing operation can determine whether a memory cell has a Vth above the associated verify voltage by applying the associated verify voltage to the control gate and sensing a current through the memory cell. If the current is relatively high, this indicates the memory cell is in a conductive state, such that the Vth is less than the control gate voltage. If the current is relatively low, this indicates the memory cell is in a non-conductive state, such that the Vth is above the control gate voltage.

The verify voltage which is used to determine that a memory cell has completed programming may be referred to as a final or lockout verify voltage. In some cases, an additional verify voltage may be used to determine that a memory cell is close to completion of the programming. This additional verify voltage may be referred to as an offset verify voltage, and may be lower than the final verify voltage. When a memory cell is close to completion of programming, the programming speed of the memory cell may be reduced such as by elevating a voltage of a respective bit line during one or more subsequent program voltages.

After the memory cells are programmed, the data can also be read back in a read operation. A read operation can involve applying a series of read voltages to a word line while sensing circuitry determines whether cells connected to the word line are in a conductive or non-conductive state. If a cell is in a non-conductive state, the Vth of the memory cell exceeds the read voltage. The read voltages are set at levels which are expected to be between the threshold voltage levels of adjacent data states.

During the read operation, if read failures exceed the capabilities of an error correction code (ECC) engine, a threshold voltage Vt tracking operation may be performed (e.g., on a selected word line) to optimize a plurality of read voltages that are associated with the data states. The read operation can then be performed again but this time with the optimized read voltages. The Vt tracking operation starts with very conservative parameters to ensure that the read voltage of a first data state is very accurately captured. Once the read voltage of the first data state has been optimized, the Vt tracking operation can be performed on the other data states using more aggressive parameters in order to improve performance while still maintaining a high degree of accuracy in capturing the optimized read voltages. However, certain situations may cause difficulties in optimizing the plurality of read voltages in the threshold voltage Vt tracking operation.

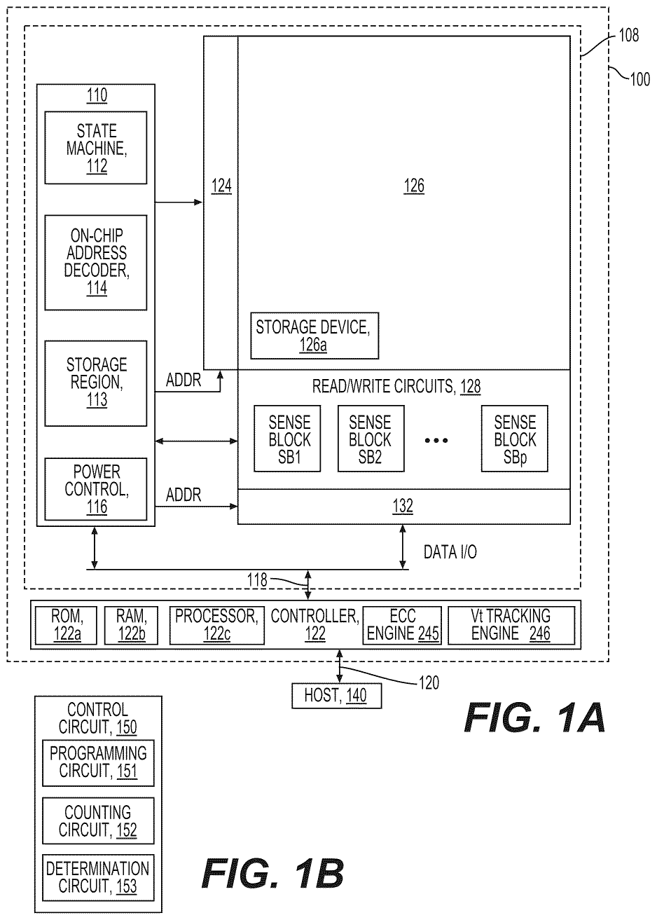

FIG. 1A is a block diagram of an example memory device 100 is configured to perform the Vt tracking operations according to the techniques of the subject disclosure. The memory die 108 includes a memory structure 126 of memory cells, such as an array of memory cells, control circuitry 110, and read/write circuits 128. The memory structure 126 is addressable by word lines via a row decoder 124 and by bit lines via a column decoder 132. The read/write circuits 128 include multiple sense blocks SB1, SB2, . . . SBp (sensing circuitry) and allow a page of memory cells to be read or programmed in parallel. Typically, a controller 122 is included in the same memory device 100 (e.g., a removable storage card) as the one or more memory die 108. Commands and data are transferred between the host 140 and controller 122 via a data bus 120, and between the controller and the one or more memory die 108 via lines 118.

The memory structure 126 can be two-dimensional or three-dimensional. The memory structure 126 may comprise one or more array of memory cells including a three-dimensional array. The memory structure 126 may comprise a monolithic three-dimensional memory structure in which multiple memory levels are formed above (and not in) a single substrate, such as a wafer, with no intervening substrates. The memory structure 126 may comprise any type of non-volatile memory that is monolithically formed in one or more physical levels of arrays of memory cells having an active area disposed above a silicon substrate. The memory structure 126 may be in a non-volatile memory device having circuitry associated with the operation of the memory cells, whether the associated circuitry is above or within the substrate.

The control circuitry 110 cooperates with the read/write circuits 128 to perform memory operations on the memory structure 126, and includes a state machine 112, an on-chip address decoder 114, and a power control module 116. The state machine 112 provides chip-level control of memory operations.

A storage region 113 may, for example, be provided for programming parameters. The programming parameters may include a program voltage, a program voltage bias, position parameters indicating positions of memory cells, contact line connector thickness parameters, a verify voltage, and/or the like. The position parameters may indicate a position of a memory cell within the entire array of NAND strings, a position of a memory cell as being within a particular NAND string group, a position of a memory cell on a particular plane, and/or the like. The contact line connector thickness parameters may indicate a thickness of a contact line connector, a substrate or material that the contact line connector is comprised of, and/or the like.

The on-chip address decoder 114 provides an address interface between that used by the host or a memory controller to the hardware address used by the decoders 124 and 132. The power control module 116 controls the power and voltages supplied to the word lines and bit lines during memory operations. It can include drivers for word lines, SGS and SGD transistors, and source lines. The sense blocks can include bit line drivers, in one approach. An SGS transistor is a select gate transistor at a source end of a NAND string, and an SGD transistor is a select gate transistor at a drain end of a NAND string.

In some embodiments, some of the components can be combined. In various designs, one or more of the components (alone or in combination), other than memory structure 126, can be thought of as at least one control circuit which is configured to perform the actions described herein. For example, a control circuit may include any one of, or a combination of, control circuitry 110, state machine 112, decoders 114/132, power control module 116, sense blocks SBb, SB2, . . . , SBp, read/write circuits 128, controller 122, and so forth.

The control circuits 150 can include a programming circuit 151 configured to perform a program and verify operation for one set of memory cells, wherein the one set of memory cells comprises memory cells assigned to represent one data state among a plurality of data states and memory cells assigned to represent another data state among the plurality of data states; the program and verify operation comprising a plurality of program and verify iterations; and in each program and verify iteration, the programming circuit performs programming for the one selected word line after which the programming circuit applies a verification signal to the selected word line. The control circuits 150 can also include a counting circuit 152 configured to obtain a count of memory cells which pass a verify test for the one data state. The control circuits 150 can also include a determination circuit 153 configured to determine, based on an amount by which the count exceeds a threshold, if a programming operation is completed.

For example, FIG. 1B is a block diagram of an example control circuit 150 which comprises the programming circuit 151, the counting circuit 152, and the determination circuit 153.

The off-chip controller 122 may comprise a processor 122c, storage devices (memory) such as ROM 122a and RAM 122b and an error-correction code (ECC) engine 245. The ECC engine can correct a number of read errors which are caused when the upper tail of a Vt distribution becomes too high. However, in some cases, the ECC engine may not be able to correct read errors. A threshold voltage Vt tracking engine 246 is provided to optimize read voltages and reduce read errors that the ECC engine cannot correct.

The storage device(s) 122a, 122b comprise, code such as a set of instructions, and the processor 122c is operable to execute the set of instructions to provide the functionality described herein. Alternately or additionally, the processor 122c can access code from a storage device 126a of the memory structure 126, such as a reserved area of memory cells in one or more word lines. For example, code can be used by the controller 122 to access the memory structure 126 such as for programming, read and erase operations. The code can include boot code and control code (e.g., set of instructions). The boot code is software that initializes the controller 122 during a booting or startup process and enables the controller 122 to access the memory structure 126. The code can be used by the controller 122 to control one or more memory structures 126. Upon being powered up, the processor 122c fetches the boot code from the ROM 122a or storage device 126a for execution, and the boot code initializes the system components and loads the control code into the RAM 122b. Once the control code is loaded into the RAM 122b, it is executed by the processor 122c. The control code includes drivers to perform basic tasks such as controlling and allocating memory, prioritizing the processing of instructions, and controlling input and output ports.

Generally, the control code can include instructions to perform the functions described herein including the steps of the flowcharts discussed further below and provide the voltage waveforms including those discussed further below. For example, the control circuitry 110, controller 122, control circuits 150, and/or any other circuitry are configured/programmed, to optimize the read voltages for a plurality of data states.

In one embodiment, the host is a computing device (e.g., laptop, desktop, smartphone, tablet, digital camera) that includes one or more processors, one or more processor readable storage devices (RAM, ROM, flash memory, hard disk drive, solid state memory) that store processor readable code (e.g., software) for programming the one or more processors to perform the methods described herein. The host may also include additional system memory, one or more input/output interfaces and/or one or more input/output devices in communication with the one or more processors.

Other types of non-volatile memory in addition to NAND flash memory can also be used.

Semiconductor memory devices include volatile memory devices, such as dynamic random access memory (“DRAM”) or static random access memory (“SRAM”) devices, non-volatile memory devices, such as resistive random access memory (“ReRAM”), electrically erasable programmable read only memory (“EEPROM”), flash memory (which can also be considered a subset of EEPROM), ferroelectric random access memory (“FRAM”), and magnetoresistive random access memory (“MRAM”), and other semiconductor elements capable of storing information. Each type of memory device may have different configurations. For example, flash memory devices may be configured in a NAND or a NOR configuration.

The memory devices can be formed from passive and/or active elements, in any combinations. By way of non-limiting example, passive semiconductor memory elements include ReRAM device elements, which in some embodiments include a resistivity switching storage element, such as an anti-fuse or phase change material, and optionally a steering element, such as a diode or transistor. Further by way of non-limiting example, active semiconductor memory elements include EEPROM and flash memory device elements, which in some embodiments include elements containing a charge storage region, such as a floating gate, conductive nanoparticles, or a charge storage dielectric material.

Multiple memory elements may be configured so that they are connected in series or so that each element is individually accessible. By way of non-limiting example, flash memory devices in a NAND configuration (NAND memory) typically contain memory elements connected in series. A NAND string is an example of a set of series-connected transistors comprising memory cells and SG transistors.

A NAND memory array may be configured so that the array is composed of multiple memory strings in which a string is composed of multiple memory elements sharing a single bit line and accessed as a group. Alternatively, memory elements may be configured so that each element is individually accessible, e.g., a NOR memory array. NAND and NOR memory configurations are examples, and memory elements may be otherwise configured. The semiconductor memory elements located within and/or over a substrate may be arranged in two or three dimensions, such as a two-dimensional memory structure or a three-dimensional memory structure.

In a two-dimensional memory structure, the semiconductor memory elements are arranged in a single plane or a single memory device level. Typically, in a two-dimensional memory structure, memory elements are arranged in a plane (e.g., in an x-y direction plane) which extends substantially parallel to a major surface of a substrate that supports the memory elements. The substrate may be a wafer over or in which the layer of the memory elements is formed or it may be a carrier substrate which is attached to the memory elements after they are formed. As a non-limiting example, the substrate may include a semiconductor such as silicon.

The memory elements may be arranged in the single memory device level in an ordered array, such as in a plurality of rows and/or columns. However, the memory elements may be arrayed in non-regular or non-orthogonal configurations. The memory elements may each have two or more electrodes or contact lines, such as bit lines and word lines.

A three-dimensional memory array is arranged so that memory elements occupy multiple planes or multiple memory device levels, thereby forming a structure in three dimensions (i.e., in the x, y and z directions, where the z-direction is substantially perpendicular and the x- and y-directions are substantially parallel to the major surface of the substrate).

As a non-limiting example, a three-dimensional memory structure may be vertically arranged as a stack of multiple two-dimensional memory device levels. As another non-limiting example, a three-dimensional memory array may be arranged as multiple vertical columns (e.g., columns extending substantially perpendicular to the major surface of the substrate, i.e., in the y direction) with each column having multiple memory elements. The columns may be arranged in a two-dimensional configuration, e.g., in an x-y plane, resulting in a three-dimensional arrangement of memory elements with elements on multiple vertically stacked memory planes. Other configurations of memory elements in three dimensions can also constitute a three-dimensional memory array.

By way of non-limiting example, in a three-dimensional array of NAND strings, the memory elements may be coupled together to form a NAND string within a single horizontal (e.g., x-y) memory device level. Alternatively, the memory elements may be coupled together to form a vertical NAND string that traverses across multiple horizontal memory device levels. Other three-dimensional configurations can be envisioned wherein some NAND strings contain memory elements in a single memory level while other strings contain memory elements which span through multiple memory levels. Three-dimensional memory arrays may also be designed in a NOR configuration and in a ReRAM configuration.

Typically, in a monolithic three-dimensional memory array, one or more memory device levels are formed above a single substrate. Optionally, the monolithic three-dimensional memory array may also have one or more memory layers at least partially within the single substrate. As a non-limiting example, the substrate may include a semiconductor such as silicon. In a monolithic three-dimensional array, the layers constituting each memory device level of the array are typically formed on the layers of the underlying memory device levels of the array. However, layers of adjacent memory device levels of a monolithic three-dimensional memory array may be shared or have intervening layers between memory device levels.

Then again, two-dimensional arrays may be formed separately and then packaged together to form a non-monolithic memory device having multiple layers of memory. For example, non-monolithic stacked memories can be constructed by forming memory levels on separate substrates and then stacking the memory levels atop each other. The substrates may be thinned or removed from the memory device levels before stacking, but as the memory device levels are initially formed over separate substrates, the resulting memory arrays are not monolithic three-dimensional memory arrays. Further, multiple two-dimensional memory arrays or three-dimensional memory arrays (monolithic or non-monolithic) may be formed on separate chips and then packaged together to form a stacked-chip memory device.

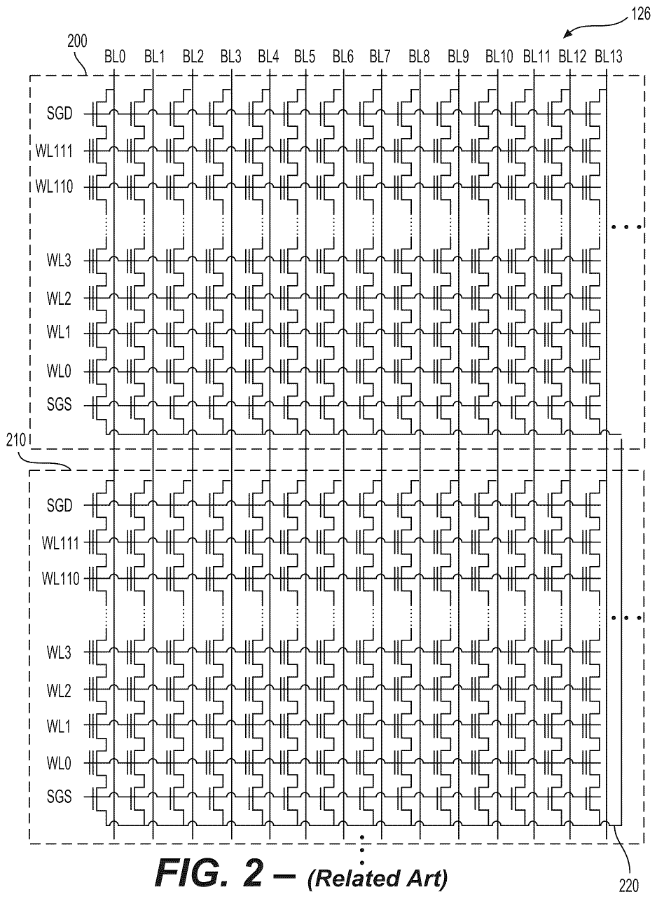

FIG. 2 illustrates memory blocks 200, 210 of memory cells in an example two-dimensional configuration of the memory array 126 of FIG. 1A. The memory array 126 can include many such blocks 200, 210. Each example block 200, 210 includes a number of NAND strings and respective bit lines, e.g., BL0, BL1, . . . which are shared among the blocks. Each NAND string is connected at one end to a drain-side select gate (SGD), and the control gates of the drain-side select gates are connected via a common SGD line. The NAND strings are connected at their other end to a source-side select gate (SGS) which, in turn, is connected to a common source line 220. One hundred and twelve word lines, for example, WL0-WL111, extend between the SGSs and the SGDs. In some embodiments, the memory block may include more or fewer than one hundred and twelve word lines. For example, in some embodiments, a memory block includes one hundred and sixty-four word lines. In some cases, dummy word lines, which contain no user data, can also be used in the memory array adjacent to the select gate transistors or between certain data word lines. Such dummy word lines can shield the edge data word line from certain edge effects.

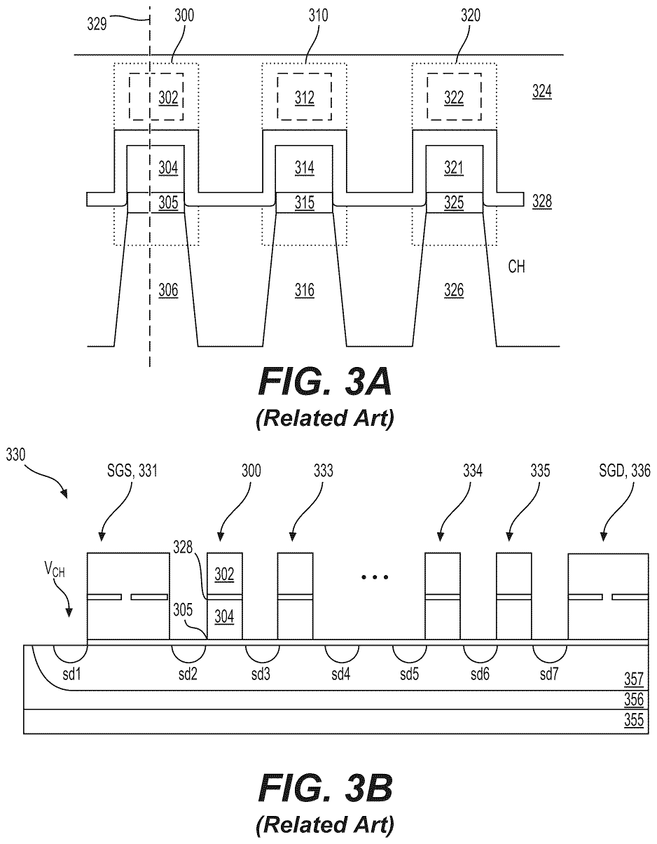

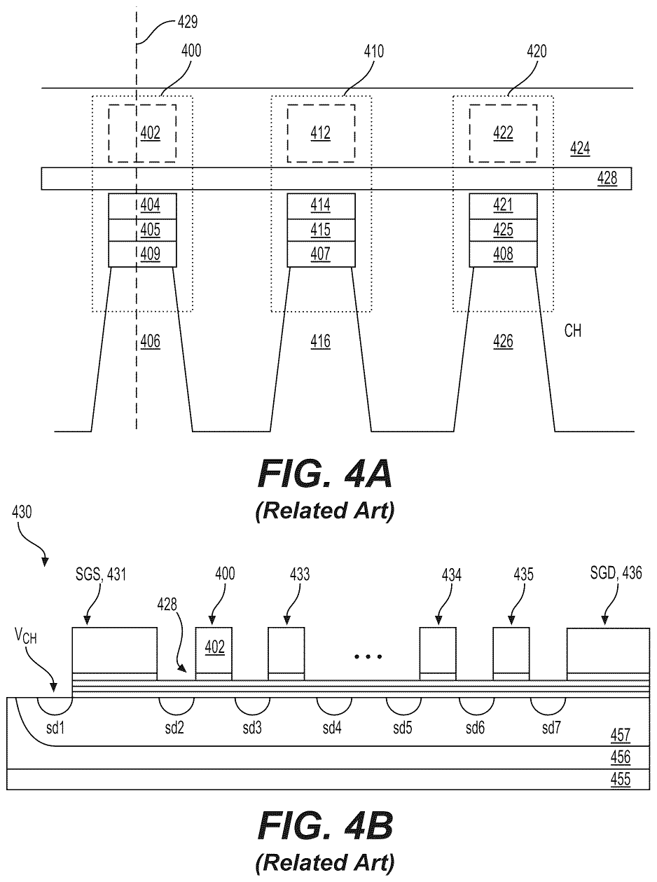

One type of non-volatile memory which may be provided in the memory array is a floating gate memory, such as of the type shown in FIGS. 3A and 3B. However, other types of non-volatile memory can also be used. As discussed in further detail below, in another example shown in FIGS. 4A and 4B, a charge-trapping memory cell uses a non-conductive dielectric material in place of a conductive floating gate to store charge in a non-volatile manner. A triple layer dielectric formed of silicon oxide, silicon nitride and silicon oxide (“ONO”) is sandwiched between a conductive control gate and a surface of a semi-conductive substrate above the memory cell channel. The cell is programmed by injecting electrons from the cell channel into the nitride, where they are trapped and stored in a limited region. This stored charge then changes the threshold voltage of a portion of the channel of the cell in a manner that is detectable. The cell is erased by injecting hot holes into the nitride. A similar cell can be provided in a split-gate configuration where a doped polysilicon gate extends over a portion of the memory cell channel to form a separate select transistor.

In another approach, NROM cells are used. Two bits, for example, are stored in each NROM cell, where an ONO dielectric layer extends across the channel between source and drain diffusions. The charge for one data bit is localized in the dielectric layer adjacent to the drain, and the charge for the other data bit localized in the dielectric layer adjacent to the source. Multi-state data storage is obtained by separately reading binary states of the spatially separated charge storage regions within the dielectric. Other types of non-volatile memory are also known.

FIG. 3A illustrates a cross-sectional view of example floating gate memory cells 300, 310, 320 in NAND strings. In this Figure, a bit line or NAND string direction goes into the page, and a word line direction goes from left to right. As an example, word line 324 extends across NAND strings which include respective channel regions 306, 316 and 326. The memory cell 300 includes a control gate 302, a floating gate 304, a tunnel oxide layer 305 and the channel region 306. The memory cell 310 includes a control gate 312, a floating gate 314, a tunnel oxide layer 315 and the channel region 316. The memory cell 320 includes a control gate 322, a floating gate 321, a tunnel oxide layer 325 and the channel region 326. Each memory cell 300, 310, 320 is in a different respective NAND string. An inter-poly dielectric (IPD) layer 328 is also illustrated. The control gates 302, 312, 322 are portions of the word line. A cross-sectional view along contact line connector 329 is provided in FIG. 3B.

The control gate 302, 312, 322 wraps around the floating gate 304, 314, 321, increasing the surface contact area between the control gate 302, 312, 322 and floating gate 304, 314, 321. This results in higher IPD capacitance, leading to a higher coupling ratio which makes programming and erase easier. However, as NAND memory devices are scaled down, the spacing between neighboring cells 300, 310, 320 becomes smaller so there is almost no space for the control gate 302, 312, 322 and the IPD layer 328 between two adjacent floating gates 302, 312, 322.

As an alternative, as shown in FIGS. 4A and 4B, the flat or planar memory cell 400, 410, 420 has been developed in which the control gate 402, 412, 422 is flat or planar; that is, it does not wrap around the floating gate and its only contact with the charge storage layer 428 is from above it. In this case, there is no advantage in having a tall floating gate. Instead, the floating gate is made much thinner. Further, the floating gate can be used to store charge, or a thin charge trap layer can be used to trap charge. This approach can avoid the issue of ballistic electron transport, where an electron can travel through the floating gate after tunneling through the tunnel oxide during programming.

FIG. 4A depicts a cross-sectional view of example charge-trapping memory cells 400, 410, 420 in NAND strings. The view is in a word line direction of memory cells 400, 410, 420 comprising a flat control gate and charge-trapping regions as a two-dimensional example of memory cells 400, 410, 420 in the memory cell array 126 of FIG. 1A. Charge-trapping memory can be used in NOR and NAND flash memory device. This technology uses an insulator such as an SiN film to store electrons, in contrast to a floating-gate MOSFET technology which uses a conductor such as doped polycrystalline silicon to store electrons. As an example, a word line 424 extends across NAND strings which include respective channel regions 406, 416, 426. Portions of the word line provide control gates 402, 412, 422. Below the word line is an IPD layer 428, charge-trapping layers 404, 414, 421, polysilicon layers 405, 415, 425, and tunneling layers 409, 407, 408. Each charge-trapping layer 404, 414, 421 extends continuously in a respective NAND string. The flat configuration of the control gate can be made thinner than a floating gate. Additionally, the memory cells can be placed closer together.

FIG. 4B illustrates a cross-sectional view of the structure of FIG. 4A along contact line connector 429. The NAND string 430 includes an SGS transistor 431, example memory cells 400, 433,. 435, and an SGD transistor 436. Passageways in the IPD layer 428 in the SGS and SGD transistors 431, 436 allow the control gate layers 402 and floating gate layers to communicate. The control gate 402 and floating gate layers may be polysilicon and the tunnel oxide layer may be silicon oxide, for instance. The IPD layer 428 can be a stack of nitrides (N) and oxides (O) such as in a N—O—N—O—N configuration.

The NAND string may be formed on a substrate which comprises a p-type substrate region 455, an n-type well 456 and a p-type well 457. N-type source/drain diffusion regions sd1, sd2, sd3, sd4, sd5, sd6 and sd7 are formed in the p-type well. A channel voltage, Vch, may be applied directly to the channel region of the substrate.

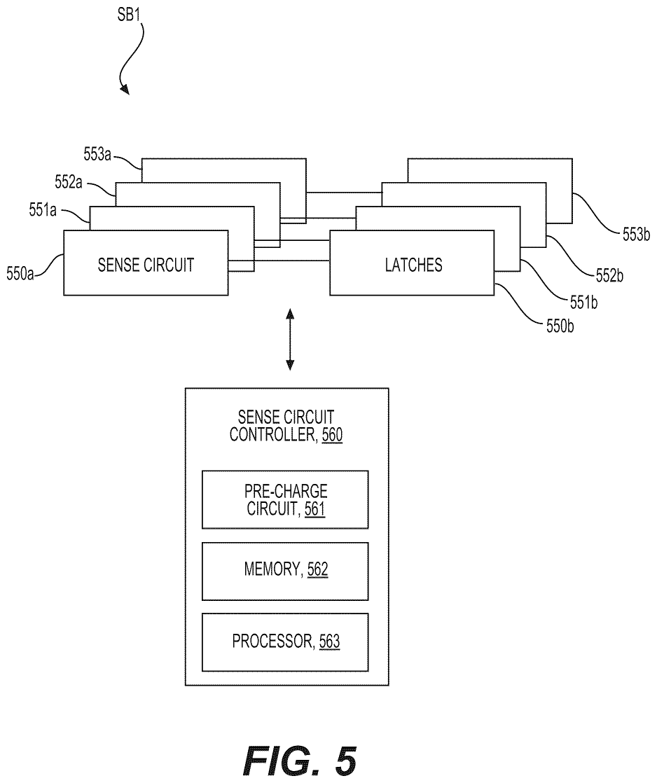

FIG. 5 illustrates an example block diagram of the sense block SB1 of FIG. 1A. In one approach, a sense block comprises multiple sense circuits. Each sense circuit is associated with data latches. For example, the example sense circuits 550a, 551a, 552a, and 553a are associated with the data latches 550b, 551b, 552b, and 553b, respectively. In one approach, different subsets of bit lines can be sensed using different respective sense blocks. This allows the processing load which is associated with the sense circuits to be divided up and handled by a respective processor in each sense block. For example, a sense circuit controller 560 in SB1 can communicate with the set of sense circuits and latches. The sense circuit controller 560 may include a pre-charge circuit 561 which provides a voltage to each sense circuit for setting a pre-charge voltage. In one possible approach, the voltage is provided to each sense circuit independently, e.g., via the data bus and a local bus. In another possible approach, a common voltage is provided to each sense circuit concurrently. The sense circuit controller 560 may also include a pre-charge circuit 561, a memory 562 and a processor 563. The memory 562 may store code which is executable by the processor to perform the functions described herein. These functions can include reading the latches 550b, 551b, 552b, 553b which are associated with the sense circuits 550a, 551a, 552a, 553a, setting bit values in the latches and providing voltages for setting pre-charge levels in sense nodes of the sense circuits 550a, 551a, 552a, 553a. Further example details of the sense circuit controller 560 and the sense circuits 550a, 551a, 552a, 553a are provided below.

In some embodiments, a memory cell may include a flag register that includes a set of latches storing flag bits. In some embodiments, a quantity of flag registers may correspond to a quantity of data states. In some embodiments, one or more flag registers may be used to control a type of verification technique used when verifying memory cells. In some embodiments, a flag bit's output may modify associated logic of the device, e.g., address decoding circuitry, such that a specified block of cells is selected. A bulk operation (e.g., an erase operation, etc.) may be carried out using the flags set in the flag register, or a combination of the flag register with the address register, as in implied addressing, or alternatively by straight addressing with the address register alone.

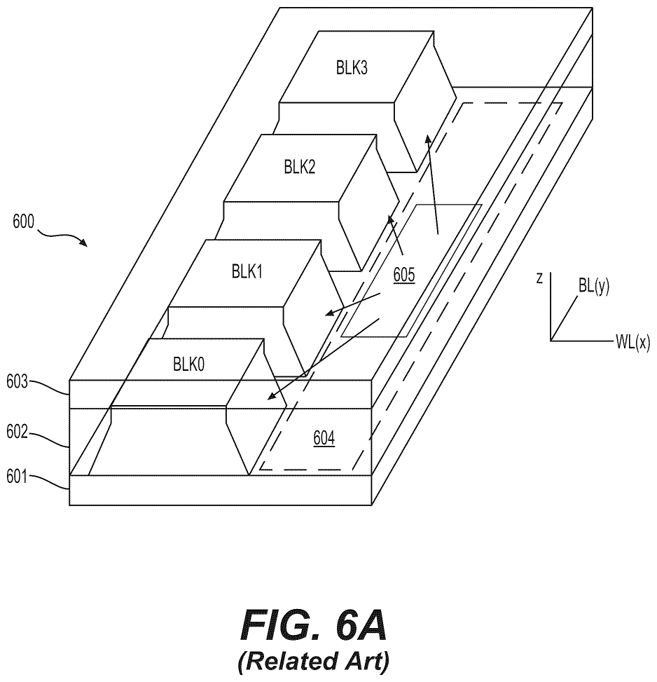

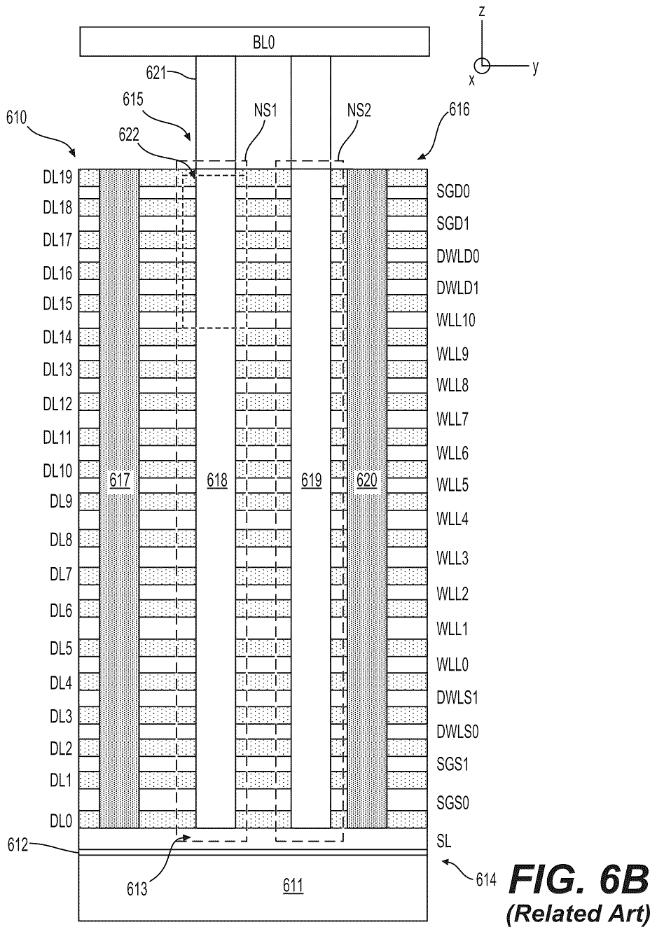

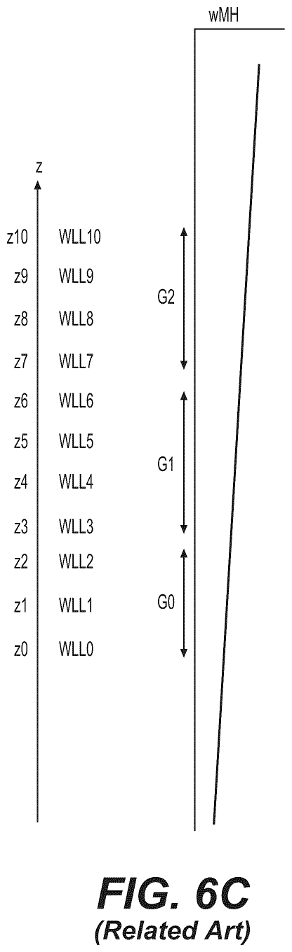

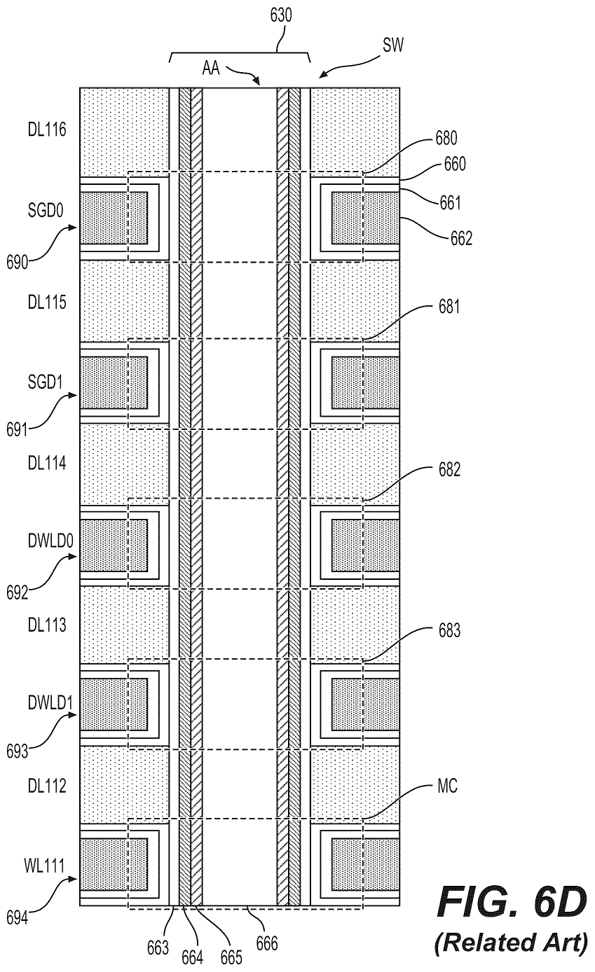

FIG. 6A is a perspective view of a set of blocks 600 in an example three-dimensional configuration of the memory array 126 of FIG. 1A. On the substrate are example blocks BLK0, BLK1, BLK2, BLK3 of memory cells (storage elements) and a peripheral area 604 with circuitry for use by the blocks BLK0, BLK1, BLK2, BLK3. For example, the circuitry can include voltage drivers 605 which can be connected to control gate layers of the blocks BLK0, BLK1, BLK2, BLK3. In one approach, control gate layers at a common height in the blocks BLK0, BLK1, BLK2, BLK3 are commonly driven. The substrate 601 can also carry circuitry under the blocks BLK0, BLK1, BLK2, BLK3, along with one or more lower metal layers which are patterned in conductive paths to carry signals of the circuitry. The blocks BLK0, BLK1, BLK2, BLK3 are formed in an intermediate region 602 of the memory device. In an upper region 603 of the memory device, one or more upper metal layers are patterned in conductive paths to carry signals of the circuitry. Each block BLK0, BLK1, BLK2, BLK3 comprises a stacked area of memory cells, where alternating levels of the stack represent word lines. In one possible approach, each block BLK0, BLK1, BLK2, BLK3 has opposing tiered sides from which vertical contacts extend upward to an upper metal layer to form connections to conductive paths. While four blocks BLK0, BLK1, BLK2, BLK3 are illustrated as an example, two or more blocks can be used, extending in the x- and/or y-directions.

In one possible approach, the length of the plane, in the x-direction, represents a direction in which signal paths to word lines extend in the one or more upper metal layers (a word line or SGD line direction), and the width of the plane, in the y-direction, represents a direction in which signal paths to bit lines extend in the one or more upper metal layers (a bit line direction). The z-direction represents a height of the memory device.

FIG. 6B illustrates an example cross-sectional view of a portion of one of the blocks BLK0, BLK1, BLK2, BLK3 of FIG. 6A. The block comprises a stack 610 of alternating conductive and dielectric layers. In this example, the conductive layers comprise two SGD layers, two SGS layers and four dummy word line layers DWLD0, DWLD1, DWLS0 and DWLS1, in addition to data word line layers (word lines) WL0-WL111. The dielectric layers are labelled as DL0-DL116. Further, regions of the stack 610 which comprise NAND strings NS1 and NS2 are illustrated. Each NAND string encompasses a memory hole 618, 619 which is filled with materials which form memory cells adjacent to the word lines. A region 622 of the stack 610 is shown in greater detail in FIG. 6D and is discussed in further detail below. The dielectric layers can have variable thicknesses such that some of the conductive layers can be closer to or further from neighboring conductive layers. The thicknesses of the dielectric layers affects the “ON pitch,” which is a factor in memory density. Specifically, a smaller ON pitch allows for more memory cells in a given area but may compromise reliability.

The stack 610 includes a substrate 611, an insulating film 612 on the substrate 611, and a portion of a source line SL. NS1 has a source-end 613 at a bottom 614 of the stack and a drain-end 615 at a top 616 of the stack 610. Contact line connectors (e.g., slits, such as metal-filled slits) 617, 620 may be provided periodically across the stack 610 as interconnects which extend through the stack 610, such as to connect the source line to a particular contact line above the stack 610. The contact line connectors 617, 620 may be used during the formation of the word lines and subsequently filled with metal. A portion of a bit line BL0 is also illustrated. A conductive via 621 connects the drain-end 615 to BL0.

FIG. 6C illustrates a plot of memory hole diameter in the stack of FIG. 6B. The vertical axis is aligned with the stack of FIG. 6B and illustrates a width (wMH), e.g., diameter, of the memory holes 618 and 619. The word line layers WL0-WL111 of FIG. 6A are repeated as an example and are at respective heights z0-z111 in the stack. In such a memory device, the memory holes which are etched through the stack have a very high aspect ratio. For example, a depth-to-diameter ratio of about 25-30 is common. The memory holes may have a circular cross-section. Due to the etching process, the memory hole width can vary along the length of the hole. Typically, the diameter becomes progressively smaller from the top to the bottom of the memory hole. That is, the memory holes are tapered, narrowing at the bottom of the stack. In some cases, a slight narrowing occurs at the top of the hole near the select gate so that the diameter becomes slightly wider before becoming progressively smaller from the top to the bottom of the memory hole.

FIG. 6D illustrates a close-up view of the region 622 of the stack 610 of FIG. 6B. Memory cells are formed at the different levels of the stack at the intersection of a word line layer and a memory hole. In this example, SGD transistors 680, 681 are provided above dummy memory cells 682, 683 and a data memory cell MC. A number of layers can be deposited along the sidewall (SW) of the memory hole 630 and/or within each word line layer, e.g., using atomic layer deposition. For example, each column (e.g., the pillar which is formed by the materials within a memory hole 630) can include a charge-trapping layer or film 663 such as SiN or other nitride, a tunneling layer 664, a polysilicon body or channel 665, and a dielectric core 666. A word line layer can include a blocking oxide/block high-k material 660, a metal barrier 661, and a conductive metal such as Tungsten as a control gate. For example, control gates 690, 691, 692, 693, and 694 are provided. In this example, all of the layers except the metal are provided in the memory hole 630. In other approaches, some of the layers can be in the control gate layer. Additional pillars are similarly formed in the different memory holes. A pillar can form a columnar active area (AA) of a NAND string.

When a memory cell is programmed, electrons are stored in a portion of the charge-trapping layer which is associated with the memory cell. These electrons are drawn into the charge-trapping layer from the channel and through the tunneling layer. The threshold voltage Vt of a memory cell is increased in proportion to the amount of stored charge. During a sensing operation, the threshold voltage Vt is detected or measured. During an erase operation, the electrons return to the channel.

Each of the memory holes 630 can be filled with a plurality of annular layers comprising a blocking oxide layer, a charge trapping layer 663, a tunneling layer 664 and a channel layer. A core region of each of the memory holes 630 is filled with a body material, and the plurality of layers are between the core region and the word line layer in each of the memory holes 630. In some cases, the charge trapping layer 663 and the tunneling layer 664 are annular in shape. In other cases, as discussed in further detail below, these layers are semi-circular in shape.

The NAND string can be considered to have a floating body channel because the length of the channel is not formed on a substrate. Further, the NAND string is provided by a plurality of word line layers above one another in a stack, and separated from one another by dielectric layers.

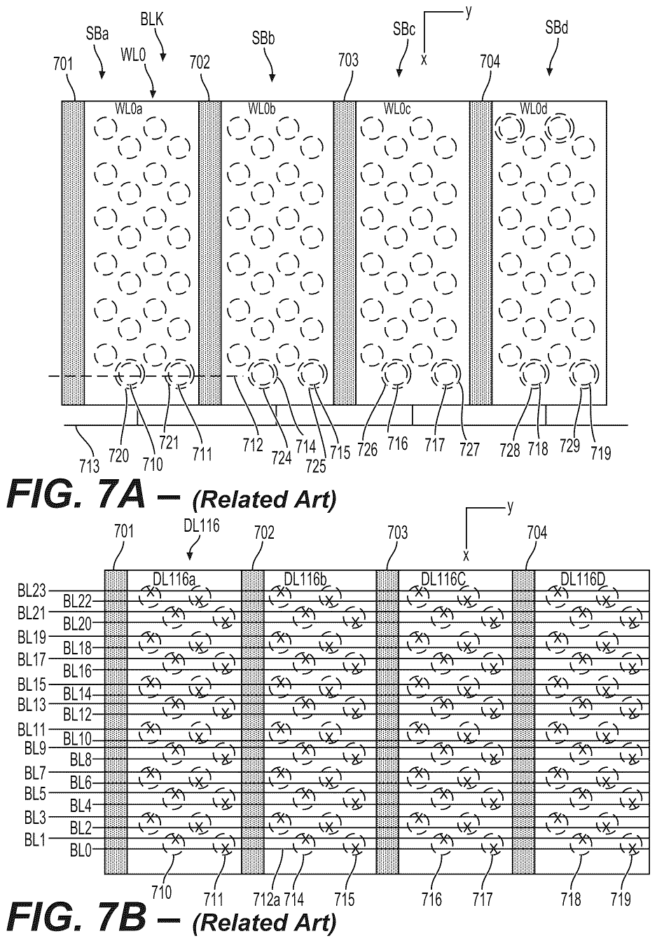

FIG. 7A illustrates a top view of an example word line layer WL0 of the stack 610 of FIG. 6B. As mentioned, a three-dimensional memory device can comprise a stack of alternating conductive and dielectric layers. The conductive layers provide the control gates of the SG transistors and memory cells. The layers used for the SG transistors are SG layers and the layers used for the memory cells are word line layers. Further, memory holes are formed in the stack and filled with a charge-trapping material and a channel material. As a result, a vertical NAND string is formed. Source lines are connected to the NAND strings below the stack and bit lines are connected to the NAND strings above the stack.

A block BLK in a three-dimensional memory device can be divided into sub-blocks, where each sub-block comprises a NAND string group which has a common SGD control line. For example, see the SGD lines/control gates SGD0, SGD1, SGD2 and SGD3 in the sub-blocks SBa, SBb, SBc and SBd, respectively. Further, a word line layer in a block can be divided into regions. Each region is in a respective sub-block and can extend between contact line connectors (e.g., slits) which are formed periodically in the stack to process the word line layers during the fabrication process of the memory device. This processing can include replacing a sacrificial material of the word line layers with metal. Generally, the distance between contact line connectors should be relatively small to account for a limit in the distance that an etchant can travel laterally to remove the sacrificial material, and that the metal can travel to fill a void which is created by the removal of the sacrificial material. For example, the distance between contact line connectors may allow for a few rows of memory holes between adjacent contact line connectors. The layout of the memory holes and contact line connectors should also account for a limit in the number of bit lines which can extend across the region while each bit line is connected to a different memory cell. After processing the word line layers, the contact line connectors can optionally be filed with metal to provide an interconnect through the stack.

In this example, there are four rows of memory holes between adjacent contact line connectors. A row here is a group of memory holes which are aligned in the x-direction. Moreover, the rows of memory holes are in a staggered pattern to increase the density of the memory holes. The word line layer or word line is divided into regions WL0a, WL0b, WL0c and WL0d which are each connected by a contact line 713. The last region of a word line layer in a block can be connected to a first region of a word line layer in a next block, in one approach. The contact line 713, in turn, is connected to a voltage driver for the word line layer. The region WL0a has example memory holes 710, 711 along a contact line 712. The region WL0b has example memory holes 714, 715. The region WL0c has example memory holes 716, 717. The region WL0d has example memory holes 718, 719. The memory holes are also shown in FIG. 7B. Each memory hole can be part of a respective NAND string. For example, the memory holes 710, 714, 716 and 718 can be part of NAND strings NS0_SBa, NS1_SBb, NS2_SBc, NS3_SBd, and NS4_SBe, respectively.

Each circle represents the cross-section of a memory hole at a word line layer or SG layer. Example circles shown with dashed lines represent memory cells which are provided by the materials in the memory hole and by the adjacent word line layer. For example, memory cells 720, 721 are in WL0a, memory cells 724, 725 are in WL0b, memory cells 726, 727 are in WL0c, and memory cells 728, 729 are in WL0d. These memory cells are at a common height in the stack.

Contact line connectors (e.g., slits, such as metal-filled slits) 701, 702, 703, 704 may be located between and adjacent to the edges of the regions WL0a-WL0d. The contact line connectors 701, 702, 703, 704 provide a conductive path from the bottom of the stack to the top of the stack. For example, a source line at the bottom of the stack may be connected to a conductive line above the stack, where the conductive line is connected to a voltage driver in a peripheral region of the memory device.

FIG. 7B illustrates a top view of an example top dielectric layer DL116 of the stack of FIG. 6B. The dielectric layer is divided into regions DL116a, DL116b, DL116c and DL116d. Each region can be connected to a respective voltage driver. This allows a set of memory cells in one region of a word line layer being programmed concurrently, with each memory cell being in a respective NAND string which is connected to a respective bit line. A voltage can be set on each bit line during each programming, sensing, or erasing operation.

The region DL116a has the example memory holes 710, 711 along a contact line 712, which is coincident with a bit line BL0. A number of bit lines extend above the memory holes and are connected to the memory holes as indicated by the “X” symbols. BL0 is connected to a set of memory holes which includes the memory holes 711, 715, 717, 719. Another example bit line BL1 is connected to a set of memory holes which includes the memory holes 710, 714, 716, 718. The contact line connectors (e.g., slits, such as metal-filled slits) 701, 702, 703, 704 from FIG. 7A are also illustrated, as they extend vertically through the stack. The bit lines can be numbered in a sequence BL0-BL23 across the DL116 layer in the x-direction.

Different subsets of bit lines are connected to memory cells in different rows. For example, BL0, BL4, BL8, BL12, BL16, BL20 are connected to memory cells in a first row of cells at the right-hand edge of each region. BL2, BL6, BL10, BL14, BL18, BL22 are connected to memory cells in an adjacent row of cells, adjacent to the first row at the right-hand edge. BL3, BL7, BL11, BL15, BL19, BL23 are connected to memory cells in a first row of cells at the left-hand edge of each region. BL1, BL5, BL9, BL13, BL17, BL21 are connected to memory cells in an adjacent row of memory cells, adjacent to the first row at the left-hand edge.

The memory cells of the memory blocks can be programmed to store one or more bits of data in multiple data states, each of which is associated with a respective threshold voltage Vt range and with a respective bit or series of bits. For example, FIG. 8 depicts a threshold voltage Vt distribution of a group of memory cells programmed according to a three bits per memory cell (TLC) storage scheme. In the TLC storage scheme, there are eight total data states, including an erased state (Er) and seven programmed data states (S1-S7). Each programmed data state (S1-S7) is associated with a respective read voltage (Vr1-Vr7), which is employed during a read or sensing operation. Other storage schemes are also available, such as one bit per memory cell (SLC) with two data states, two bits per cell (MLC) with four data states, four bits per cell (QLC) with sixteen data states, or five bits per cell (PLC) with thirty-two data states.

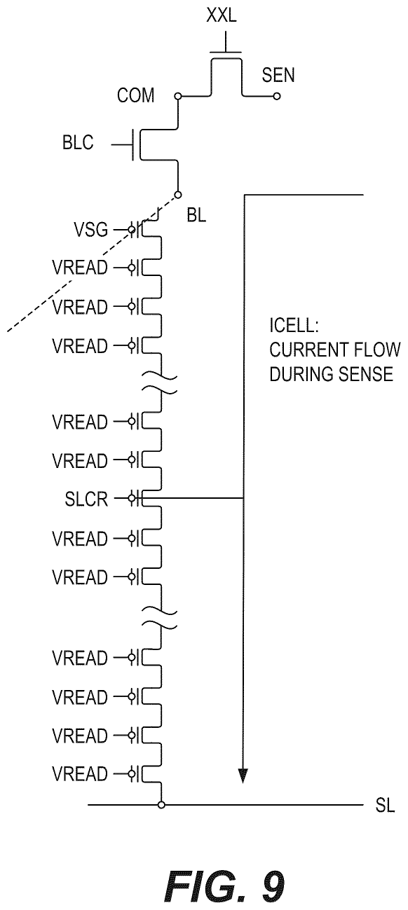

Turning now to FIG. 9, a sensing operation (verify or read) begins with a sense node SEN on the drain side of the memory block being charged to a predetermined charged voltage. Simultaneously, all of the memory cells of a selected NAND string, which contains a selected memory cell of a selected word line WLn, except the selected memory cell are turned on by a pass voltage VREAD. A reference voltage VCG (e.g., any of the read voltages Vr in FIG. 8) is applied to a control gate of the selected word line WLn. The sense node SEN is then discharged through the NAND string. Since all of the memory cells except the selected memory cell are definitely turned on by the pass voltage VREAD, the discharge current Icell through the NAND string is largely dictated by the threshold voltage Vt of the selected memory cell. At a discharge time T_sense, a voltage on the SEN node is sensed by the sensing circuitry and compared to V_sense, which is the threshold voltage Vt of a AVPGM sensing transistor. If the threshold voltage Vt of the selected memory cell being sensed is higher than the reference voltage VCG, then the selected memory cell is was not turned on by the reference voltage VCG and conducts a very small/negligible current resulting in only a small discharge of SEN node voltage. Thus, the SEN node voltage will remain higher than V_sense. On the other hand, if the threshold voltage Vt of the selected memory cell being sensed is lower than the reference voltage VCG, then the reference voltage VCG will turn on the selected memory cell and a larger discharging current will resulting in the SEN node having a lower voltage than V_sense. This process is performed for each memory cell of the selected word line WLn to read the data stored in the memory cells of the selected word line WLn.

Over time, the threshold voltages Vt of the memory cells can shift, or drift, either upward or downward due to a range of factors, such as charge leakage, read disturb, large temperature changes, etc. Thus, the optimum reference voltages for reading that data can shift over time as well. If enough shifting occurs, then some memory cells in a selected word line being read will read as failed bits. The ECC engine can correct a certain number of failed bits, but if the number of failed bits exceeds the capabilities of the ECC engine, then a read error will occur. In some instances, a Vt tracking operation (sometimes also known as valley search) may be performed to in response to a read error to determine optimal read voltages Vr1-Vr7 for the programmed data states. The read operation can then be tried again with the optimized read voltages Vr1-Vr7 and, in many cases, it will pass.

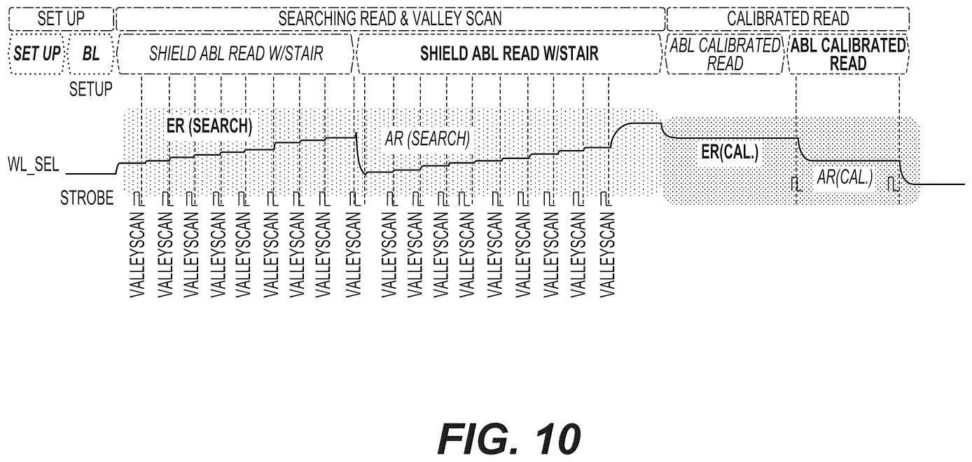

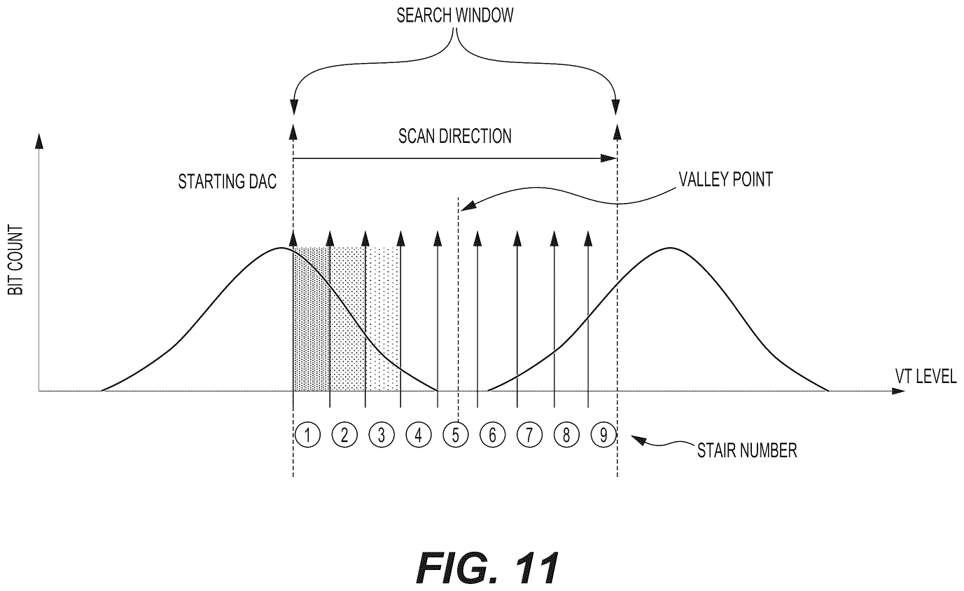

FIG. 10 is a waveform of a valley search or threshold voltage Vt tracking operation. The threshold voltage Vt tracking operation is performed on memory cells connected to the selected word line, WL_sel and is done as part of a lower page (data states S5 or E and S1 or A). FIG. 11 is a plot of threshold voltage distributions for two adjacent data states and illustrates a specific valley search scan or threshold voltage Vt tracking method. In the specific Vt tracking method, a group of memory cells (e.g., connected to a selected word line) are evaluated using multiple discrete sensing voltages for certain predetermined data states. In the example illustrated in FIG. 11, there are nine distinct sensing voltages at each of a plurality of stair numbers, labeled (1) through (9). The process begins with an initial sensing voltage (1), termed the “starting DAC,” and progresses incrementally from to a final sensing voltage (9). After each sensing voltage is applied to the selected word line and a read operation is conducted, the quantity of memory cells with threshold voltages Vt either above or below the applied sensing voltage is tallied. These counts are used to ascertain the number of memory cells within the voltage intervals defined by consecutive sensing voltages. In this scenario, there are eight voltage ranges to consider: the first voltage range being between sensing voltages (1) and (2), the second voltage range being between sensing voltages (2) and (3), and so on, up to the eighth voltage range that is between sensing voltages (8) and (9).

For instance, if an initial count reveals 100 memory cells with threshold voltages Vt above the first sensing voltage (1), and a subsequent count identifies only 50 above the second sensing voltage (2), it can be inferred that 50 memory cells fall within the first voltage range. The voltage range that contains the smallest number of memory cells is identified as the “valley” and signifies the transition between two data states. The optimized read voltage (at the valley point) for the data state in question (the data state having the threshold voltage distribution on the right hand side of FIG. 11 in this example) is then set at the midpoint of this “valley” range. Taking FIG. 11 as a reference, the valley is found between sensing voltages (5) and (6), which means the read voltage Vr for the upper of the two data states on either side of the valley is determined by averaging the values of sensing voltages (5) and (6).

To precisely identify the voltage region separating two distinct data states and to determine the most effective read voltage Vr, it is essential to initiate the search operation at a voltage level below and conclude it above the valley's actual voltage. The granularity of the sensing voltages plays a pivotal role in the accuracy of this process. Specifically, employing a finer resolution of sensing voltages, which means a reduced interval between them, enhances the detection precision of the valley. Nonetheless, expanding the voltage range of the valley search operation and increasing resolution have their trade-offs. Expanding the voltage range for the search and narrowing the intervals between sensing voltages both contribute to a longer for the valley search operation. This, in turn, can impede the overall performance of the NAND memory device. Consequently, achieving an optimal balance in setting the initial and final sensing voltages, as well as the increments between them, is crucial for efficient memory performance and reliability.

The selection of an optimal starting digital-to-analog converter (DAC) voltage for the Vt tracking process in is influenced by the total number of sensing voltages applied and the incremental voltage difference between them.

As discussed, certain situations may cause difficulties in optimizing the plurality of read voltages in the threshold voltage Vt tracking operation. As above, such threshold voltage Vt tracking or valley search read is a read method that detects the valley for optimal read level especially after data retention (DR). Referring back to FIG. 11, the starting DAC is pre-set for each data state, then a bit count is obtained during a read at each stair number. The total window to find the valley point is determined by a maximum stair number.

Typically, a pre-read was performed, each state has a starting read level position (starting DAC), then scan through a number of steps (stair number), with a defined step size (default 25 mV), then finds the lowest bitscan region (also called stair number), after applying certain algorithm, it finds the optimal offset and use it as the updated read level in the actual read. In order to find the optimal read level (also called valley point), the stair number needs to be set at a large enough range in order to ensure large search window to cover all word lines (WL), all DR cases. The stair number (also called “Max Stair Number”), may be set to 14. However, after long term DR, the downshift of the valley point of the read level for a certain data state (e.g., S7 or G data state) will overlap with an adjacent, lower (N-1) data state fresh memory cell valley point (e.g., S6 or F data state), and thus finding the wrong read level.

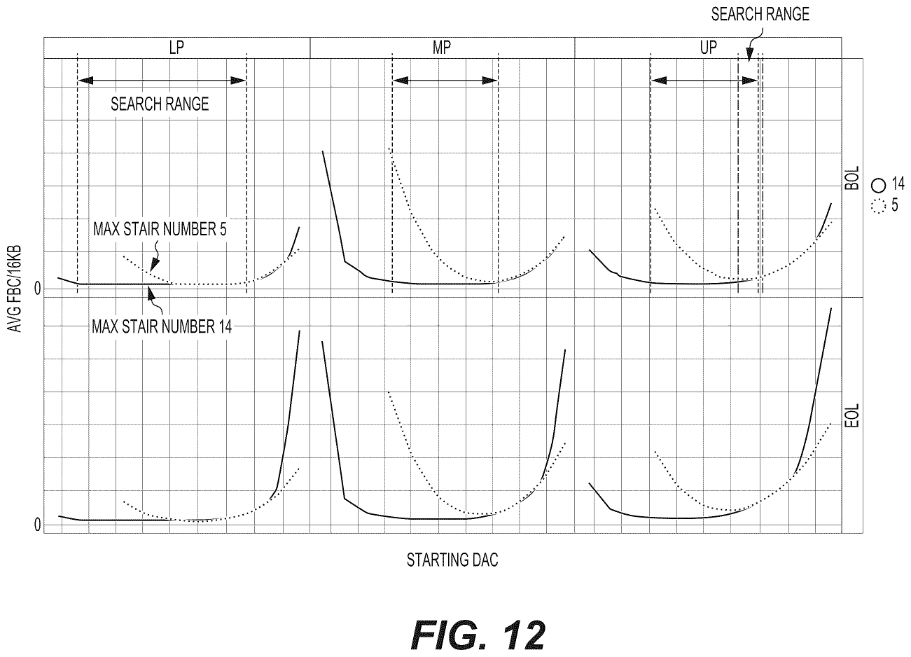

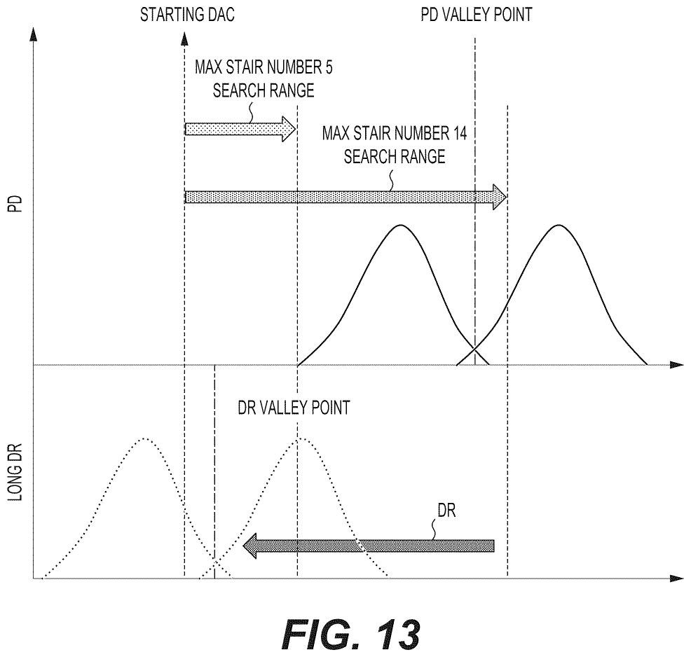

FIG. 12 shows plots of failure bit count (FBC) versus starting DAC with the maximum stair number equal to 14. As shown, there is relatively low FBC throughout a 20 DAC increment range for all pages, whereas with the maximum stair number equal to 5, only 5 DAC increments of search range is realized. So, the number of stairs directly impacts the search range, in the above case, step size is 2 DAC increments, 14 stairs provides around 20 DAC increments of search range which 5 stairs only results in roughly a 5 DAC increment search range. Therefore in order to cover the shift from fresh memory cells (PD) to long term DR, the starting DAC will need to be at the most negative value which the valley point can reach, as shown in FIG. 13, which shows plots of threshold voltage distributions for two adjacent data states for fresh (PD) memory cells and after long data retention (long DR) and illustrates how the maximum stair number affects the search range. Thus, the maximum stair number and step size will need to cover all the way up to PD valley point to ensure both read levels can be detected.

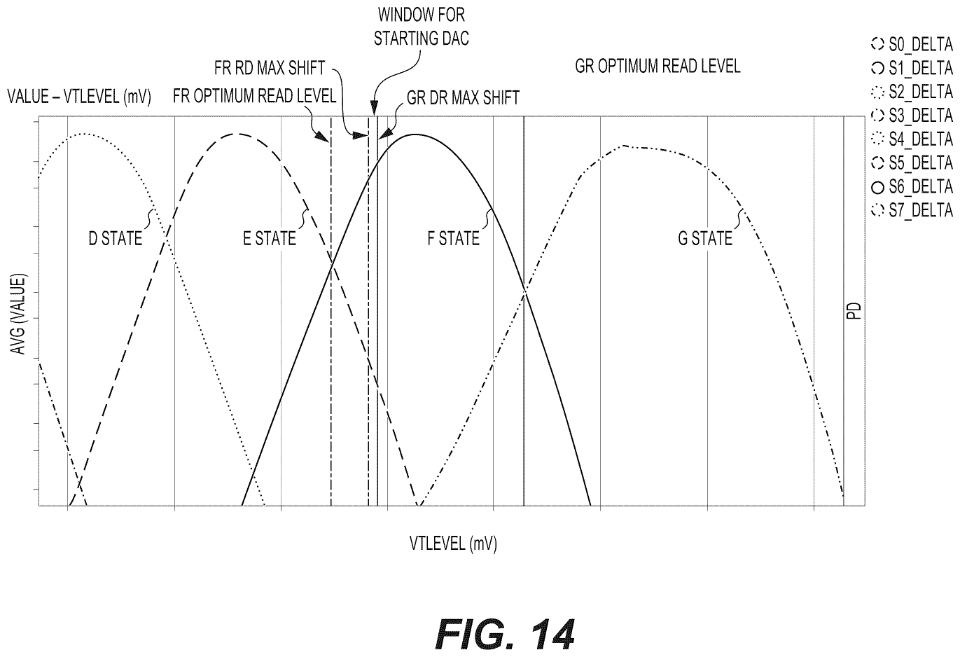

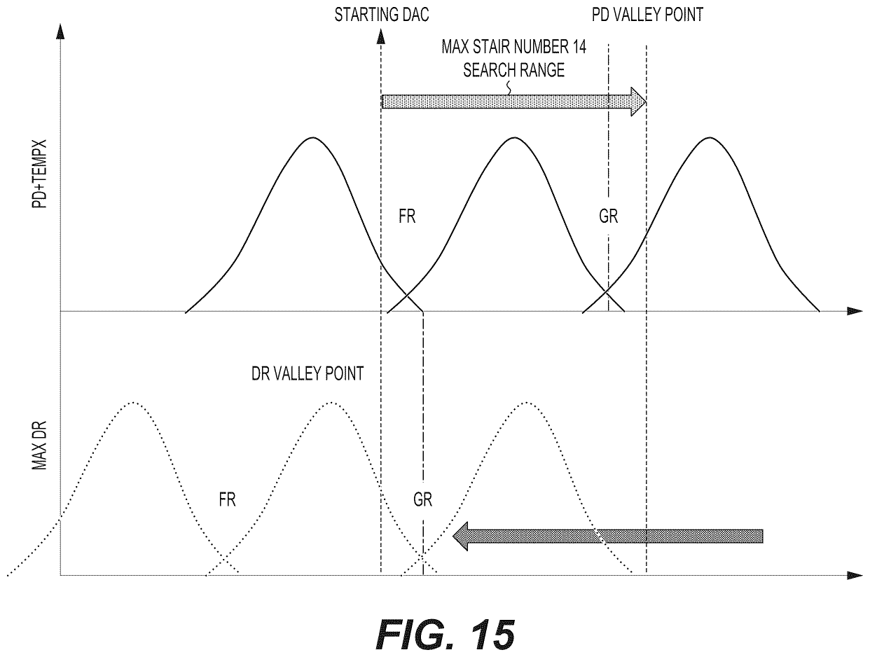

FIG. 14 is a plot of threshold voltage distributions of memory cells programmed to different data states for fresh (PD case) memory cells and shows different shifts of the read levels after data retention (DR) depending on the data state. For example, the G data state read level (GR) down shift by 679 mV whereas the F data state read level (FR) or tempX case will upshift 175 mV from fresh to data retention. FIG. 15 shows plots of threshold voltage distributions for three adjacent data states for fresh (PD) memory cells accounting for maximum temperature variations (TempX) and after long data retention (maximum DR). As shown in FIG. 15, for example, there is a risk of discovering valley point for the F data state read level instead of the G data state read level. For some memory devices or apparatuses, DR coverage will need to ensure up to 10 years at 55 degrees Celsius. The max DR shift for the G data state can reach up to −670 mV. On the other hand, the tempX and read disturb (RD) shift up can reach up to +175 mV. Therefore, the total search window for the threshold voltage Vt tracking operation will need to be at least ~845 mV to ensure both DR and tempX/RD cases.

As shown in FIG. 14, for example, For PD, read level delta for G and F data states is only approximately 900 mV, this gives very small window for the threshold voltage Vt tracking starting DAC. When scanning through the read level or voltage for the G state (GR), it is very likely that the read level or voltage for the F state (FR) in the PD condition is also being detected. When threshold voltage Vt tracking searching this valley, it cannot be determined whether this is FR or GR. Such an issue will cause an incorrect read level being applied (applying F state read level to GR read) during calibrated read (FIG. 10) and failure bit count (FBC) will significantly increase. Referring back to FIG. 15, in the example of the PD case and the long DR case, the start DAC and search window can cover both cases for GR read, but FR in PD will run into the search range, and therefore FR state will be used as the new read level for GR state in PD case.

Consequently, described herein is a memory apparatus (e.g., memory device 100 in FIG. 1A) including memory cells (e.g., memory cell MC in FIG. 6D) each connected to one of a plurality of word lines (e.g., word lines WL0-WL111 of FIG. 2 or word line layers WLL0 WLL10 of FIG. 6B) and disposed in memory holes (e.g., memory hole 618, 619 of FIG. 6B). The memory cells are configured to retain a threshold voltage Vth corresponding to one of a plurality of data states (e.g., Er, A or S1, B or S2, C of S3, D or S4, E or S5, For S6 and G or S7 data states in FIG. 8). The memory apparatus also includes a control means (e.g., control circuitry 110, controller 122, decoders 124, 132, read/write circuits 128, and sense blocks SB1, SB2, SBp in FIG. 1A, control circuit 150 in FIG. 1B) configured to detect a valley point (FIG. 11) between distributions of the threshold voltage of two of the plurality of data states for a group of the memory cells in a threshold voltage tracking operation. The control means is also configured to determine whether the valley point is between a first identified one (e.g., the E or S5 data state) of the plurality of data states and a second identified one (e.g., the F or S6 data state) of the plurality of data states or between the second identified one (e.g., the For S6 data state) of the plurality of data states and a third identified one (e.g., the G or S7 data state) of the plurality of data states and set an optimal read level for one of the plurality of data states based on a count of the memory cells associated with the valley point (i.e., an improved threshold voltage Vt tracking operation). Accordingly, the downshift of the valley point after long term data retention issue described above can be solved by actually counting the bits.

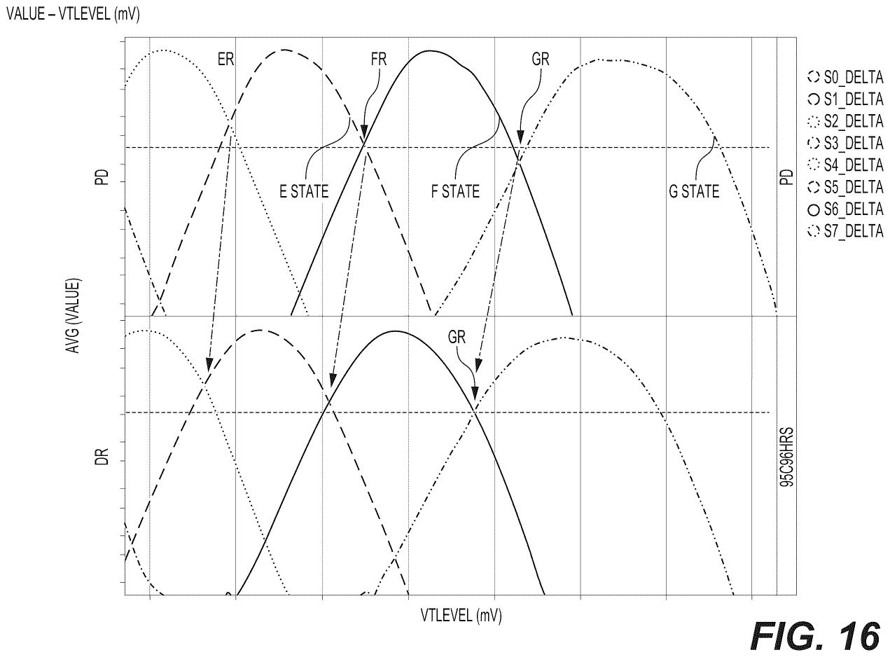

FIG. 16 is a plot of threshold voltage distributions of memory cells programmed to different data states for fresh (PD) memory cells and for the memory cells after data retention (DR). The bitcount (BC) at the valley point can be determined, here BC is defined as the exact number of bits at the given read level. So, using the improved threshold voltage Vt tracking operation, whether the valley point detected is for the GR or FR state, for example. As shown, in FIG. 16, the GR state after 95 C 96 hrs of DR shows a large increase in bit count (40 bits/ 4 KB) compared to PD (20 bits/4 KB), this is due to GR state downshifting faster than FR state during data retention, which further causes the bitcount at the valley point to increase. Therefore, by the time when GR read DR downshift occurs too close to FR read, the number of bitcount will be at least 2× or more higher than that of FR during PD. In the example of FIG. 16, the GR valley BC is already higher than FR valley BC after 95 C 96 hours. Similarly for FR and ER read, BC is at least 2× higher after 95 C 96 hours compare to PD. In the example of FIG. 15, if the threshold voltage Vt tracking operation detects the valley point or valley for the GR read, it can differentiate whether this is FR or GR by using the total number of bitcount (i.e., the count of the memory cells associated with the valley point). Accordingly, the memory apparatus can include and utilize one parameter for each of the plurality of data states for the valley search. These parameters each define the threshold of the bitcount (BC) for the data state. If the detected BC is below the threshold, then it is considered as data state of adjacent and associated with a lower threshold voltage (N-1 data state). For example, when doing GR read, if the detected BC is lower than the threshold parameter for the G data state, then it is determined as FR read level and will continue to look for the second valley.

Thus, according to an aspect and as part of a first improved threshold voltage Vt tracking operation, the control means is further configured to calculate a difference count equal to a difference between a first quantity of the memory cells of the group having the threshold voltage above a first threshold voltage stair sensing voltage associated with the valley point and a second quantity of the memory cells having the threshold voltage above a second threshold voltage stair sensing voltage associated with the valley point. The control means then determines the valley point is between the first identified one (e.g., E or S5 data state) of the plurality of data states and the second identified one (e.g., F of S6 data state) of the plurality of data states and sets a second identified optimal read level for the second identified one (e.g., F or S6 data state) of the plurality of data states as the threshold voltage corresponding to the valley point in response to the difference count being less than a predetermined threshold count associated with the third identified one (e.g., Gor S7 data state) of the plurality of data states. The control means is also configured to determine the valley point is between a second identified one (e.g., F or S6 data state) of the plurality of data states and the third identified one (e.g., G or S7 data state) of the plurality of data states and set a third identified optimal read level for the third identified one (e.g., G or S7 data state) of the plurality of data states as the threshold voltage corresponding to the valley point in response to the difference count not being less than the predetermined threshold count associated with the third identified one (e.g., G of S7 data state) of the plurality of data states.

Referring back to FIG. 8 for example, and as discussed, each of the memory cells can be configured to store three bits. So, the plurality of data states include, in order of the threshold voltage increasing, an erase data state (Er) and a first programmed data state (e.g., the S1 or A data state) and a second programmed data state (e.g., the S2 or B data state) and a third programmed data state (e.g., the S3 or C data state) and a fourth programmed data state (e.g., the S4 or D data state) and a fifth programmed data state (e.g., the S5 or E data state) and a sixth programmed data state (e.g., the S6 or F data state) and a seventh programmed data state (e.g., the S7 or G data state). So, according to an aspect of the disclosure, the first identified one of the plurality of data states is the fifth programmed data state (e.g., the S5 or E data state) and the second identified one of the plurality of data states is the sixth programmed data state (e.g., the S6 or F data state) and the third identified one of the plurality of data states is the seventh programmed data state (e.g., the S7 or G data state).

According to further aspects, for the first improved threshold voltage Vt tracking operation, the control means may be further configured to continue scanning for another valley point between the second identified one of the plurality of data states and the third identified one of the plurality of data states in response to the difference count being less than a predetermined threshold count associated with the third identified one of the plurality of data states.

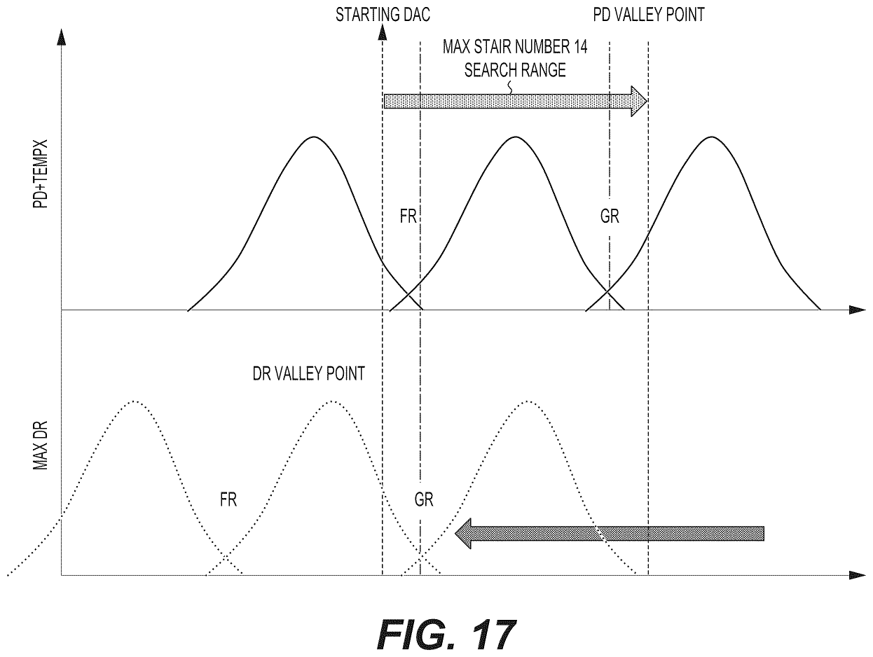

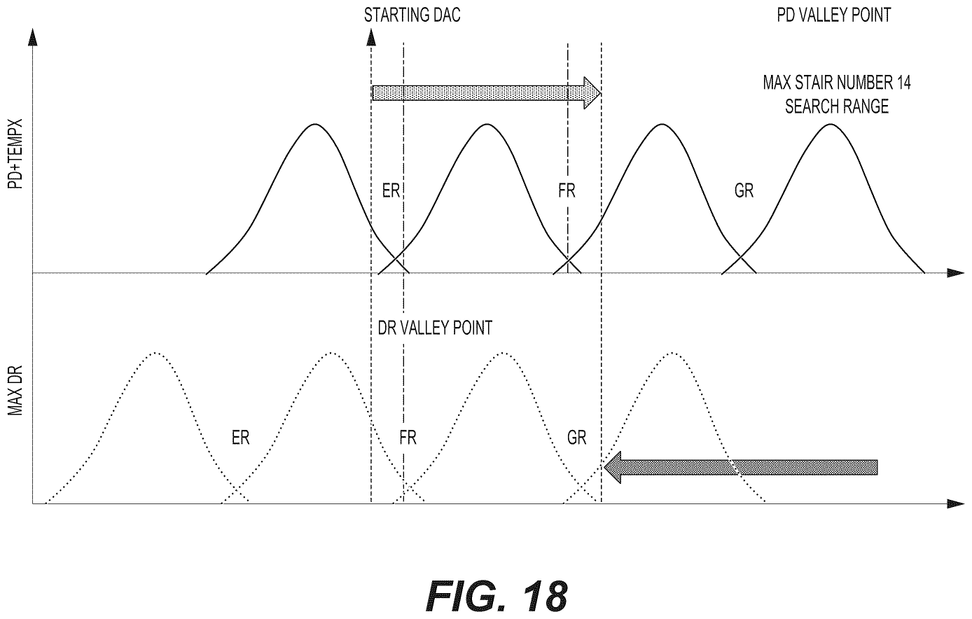

FIG. 17 shows plots of threshold voltage distributions for three adjacent data states for fresh (PD) memory cells accounting for maximum temperature variations (TempX) and after long data retention (maximum DR) and illustrates a predetermined read level (indicated as number 1 circled). FIG. 18 shows plots of threshold voltage distributions for four adjacent data states for fresh (PD) memory cells accounting for maximum temperature variations (TempX) and after long data retention (maximum DR) and illustrates another predetermined read level (indicated as number 2 circled).

Using a similar concept as in the first improved threshold voltage Vt tracking operation described above, the total bits above a given read level can be used to differentiate between the data states in a second improved threshold voltage Vt tracking operation. For example, when reading at a particular read level, all cells above are “0”s and all cells below are “1”s. The amount of “0”s will be about 2/8 of the total population (e.g. 1 KB in a 4 KB reading) in the case of PD since there are two states above it. After long DR, the amount of “0”s will be around 1/8 of the total population, as in the case of “Max DR” shown in FIG. 17. Furthermore, as shown in FIG. 18, the concept can be applied to other data states, for example, in FIG. 18, the valley scan is to search for FR valley point. While in read level PD situation, the total number of “0” bits will be ⅜ of the population, whereas after DR, the total number of “0” bits will decrease to 2/8.

Therefore, according to other aspects and as part of the second improved threshold voltage Vt tracking operation, the control means is further configured to read the memory cells of the group at a predetermined read level associated with a second identified one (e.g., For S6 data state) and a third identified one (e.g., G or S7 data state) of the plurality of data states and count a cell quantity of the memory cells of the group having the threshold voltage greater than the predetermined read level. In addition, the control means is configured to set a second identified optimal read level for the second identified one (e.g., F or S6 data state) of the plurality of data states as the threshold voltage corresponding to the valley point in response to the cell quantity being approximately equal to a second predetermined expected amount of the memory cells for the second identified one (e.g., For S6 data state) of the plurality of data states. The control means is also configured to set a third identified optimal read level for the third identified one (e.g., G or S7 data state) of the plurality of data states as the threshold voltage corresponding to the valley point in response to the cell quantity being approximately equal to a third predetermined expected amount of the memory cells for the third identified one (e.g., G or S7 data state) of the plurality of data states. According to further aspects, for the second improved threshold voltage Vt tracking operation, the group of the memory cells comprises the memory cells connected to a predetermined quantity of the plurality of word lines (e.g., one).

According to additional aspects of the disclosure, for the second improved threshold voltage Vt tracking operation, the first identified one of the plurality of data states is the fifth programmed data state and the second identified one of the plurality of data states is the sixth programmed data state and the third identified one of the plurality of data states is the seventh programmed data state. The second predetermined expected amount of the memory cells is approximately equal to two eighths of a total quantity of the memory cells of the group and the third predetermined expected amount of the memory cells is approximately equal to one eighths of the total quantity of the memory cells of the group.

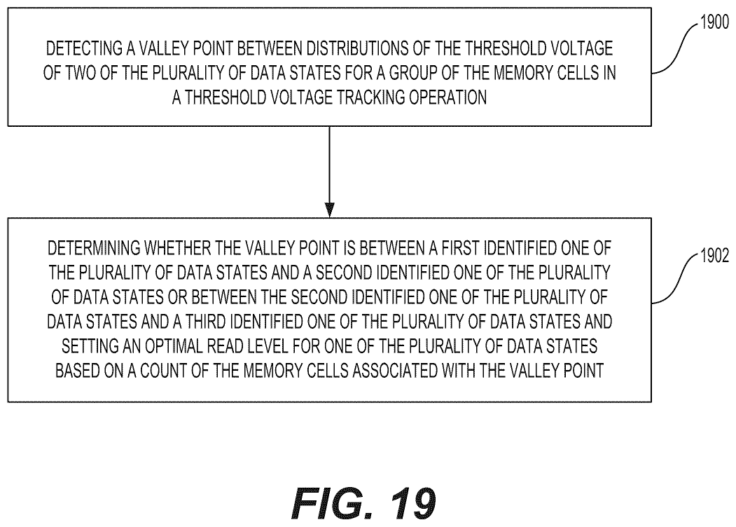

Now referring to FIG. 19, a method of operating a memory apparatus is also provided. As discussed above, the memory apparatus (e.g., memory device 100 in FIG. 1A) includes memory cells (e.g., memory cell MC in FIG. 6D) each connected to one of a plurality of word lines (e.g., word lines WL0-WL111 of FIG. 2 or word line layers WLL0-WLL10 of FIG. 6B) and disposed in memory holes (e.g., memory hole 618, 619 of FIG. 6B). The memory cells are configured to retain a threshold voltage Vth corresponding to one of a plurality of data states (e.g., Er, A or S1, B or S2, C of S3, D or S4, E or S5, For S6 and G or S7 data states in FIG. 8). The method includes the step of 1900 detecting a valley point between distributions of the threshold voltage of two of the plurality of data states for a group of the memory cells in a threshold voltage tracking operation. The method also includes the step of 1902 determining whether the valley point is between a first identified one (e.g., the E or S5 data state) of the plurality of data states and a second identified one (e.g., the F or S6 data state) of the plurality of data states or between the second identified one (e.g., the F or S6 data state) of the plurality of data states and a third identified one (e.g., the G or S7 data state) of the plurality of data states and setting an optimal read level for one of the plurality of data states based on a count of the memory cells associated with the valley point.

According to an aspect and as part of the first improved threshold voltage Vt tracking operation, the method further includes the step of calculating a difference count equal to a difference between a first quantity of the memory cells of the group having the threshold voltage above a first threshold voltage stair sensing voltage associated with the valley point and a second quantity of the memory cells having the threshold voltage above a second threshold voltage stair sensing voltage associated with the valley point. The method additionally includes the step of determining the valley point is between the first identified one (e.g., E or S5 data state) of the plurality of data states and the second identified one (e.g., F of S6 data state) of the plurality of data states and setting a second identified optimal read level for the second identified one (e.g., F or S6 data state) of the plurality of data states as the threshold voltage corresponding to the valley point in response to the difference count being less than a predetermined threshold count associated with the third identified one (e.g., G or S7 data state) of the plurality of data states. The method also includes the step of determining the valley point is between a second identified one (e.g., For S6 data state) of the plurality of data states and the third identified one (e.g., G or S7 data state) of the plurality of data states and setting a third identified optimal read level for the third identified one (e.g., G or S7 data state) of the plurality of data states as the threshold voltage corresponding to the valley point in response to the difference count not being less than the predetermined threshold count associated with the third identified one (e.g., G of S7 data state) of the plurality of data states.

Again, referring back to FIG. 8 for example, and as discussed, each of the memory cells can be configured to store three bits. Therefore, the plurality of data states include, in order of the threshold voltage increasing, an erase data state (Er) and a first programmed data state (e.g., the S1 or A data state) and a second programmed data state (e.g., the S2 or B data state) and a third programmed data state (e.g., the S3 or C data state) and a fourth programmed data state (e.g., the S4 or D data state) and a fifth programmed data state (e.g., the S5 or E data state) and a sixth programmed data state (e.g., the S6 or F data state) and a seventh programmed data state (e.g., the S7 or G data state). So, according to an aspect of the disclosure, the first identified one of the plurality of data states is the fifth programmed data state (e.g., the S5 or E data state) and the second identified one of the plurality of data states is the sixth programmed data state (e.g., the S6 or F data state) and the third identified one of the plurality of data states is the seventh programmed data state (e.g., the S7 or G data state).

According to other aspects, for the first improved threshold voltage Vt tracking operation, the method further includes the step of continuing scanning for another valley point between the second identified one of the plurality of data states and the third identified one of the plurality of data states in response to the difference count being less than a predetermined threshold count associated with the third identified one of the plurality of data states.

Again, using a similar concept as in the first improved threshold voltage Vt tracking operation described above, the total bits above a given read level can be used to differentiate between the data states in the second improved threshold voltage Vt tracking operation. Thus, according to other aspects and as part of the second improved threshold voltage Vt tracking operation, the method further includes the step of reading the memory cells of the group at a predetermined read level associated with a second identified one (e.g., F or S6 data state) and a third identified one (e.g., G or S7 data state) of the plurality of data states and count a cell quantity of the memory cells of the group having the threshold voltage greater than the predetermined read level. Furthermore, the method includes the step of setting a second identified optimal read level for the second identified one (e.g., F or S6 data state) of the plurality of data states as the threshold voltage corresponding to the valley point in response to the cell quantity being approximately equal to a second predetermined expected amount of the memory cells for the second identified one (e.g., For S6 data state) of the plurality of data states. The method also includes the step of setting a third identified optimal read level for the third identified one (e.g., G or S7 data state) of the plurality of data states as the threshold voltage corresponding to the valley point in response to the cell quantity being approximately equal to a third predetermined expected amount of the memory cells for the third identified one (e.g., G or S7 data state) of the plurality of data states. As above and according to additional aspects, for the second improved threshold voltage Vt tracking operation, the group of the memory cells comprises the memory cells connected to a predetermined quantity of the plurality of word lines (e.g., one).

According to other aspects of and as discussed above, for the second improved threshold voltage Vt tracking operation, the first identified one of the plurality of data states is the fifth programmed data state and the second identified one of the plurality of data states is the sixth programmed data state and the third identified one of the plurality of data states is the seventh programmed data state. The second predetermined expected amount of the memory cells is approximately equal to two eighths of a total quantity of the memory cells of the group and the third predetermined expected amount of the memory cells is approximately equal to one eighths of the total quantity of the memory cells of the group.

Various terms are used herein to refer to particular system components. Different companies may refer to a same or similar component by different names and this description does not intend to distinguish between components that differ in name but not in function. To the extent that various functional units described in the following disclosure are referred to as “modules,” such a characterization is intended to not unduly restrict the range of potential implementation mechanisms. For example, a “module” could be implemented as a hardware circuit that includes customized very-large-scale integration (VLSI) circuits or gate arrays, or off-the-shelf semiconductors that include logic chips, transistors, or other discrete components. In a further example, a module may also be implemented in a programmable hardware device such as a field programmable gate array (FPGA), programmable array logic, a programmable logic device, or the like. Furthermore, a module may also, at least in part, be implemented by software executed by various types of processors. For example, a module may comprise a segment of executable code constituting one or more physical or logical blocks of computer instructions that translate into an object, process, or function. Also, it is not required that the executable portions of such a module be physically located together, but rather, may comprise disparate instructions that are stored in different locations and which, when executed together, comprise the identified module and achieve the stated purpose of that module. The executable code may comprise just a single instruction or a set of multiple instructions, as well as be distributed over different code segments, or among different programs, or across several memory devices, etc. In a software, or partial software, module implementation, the software portions may be stored on one or more computer-readable and/or executable storage media that include, but are not limited to, an electronic, magnetic, optical, electromagnetic, infrared, or semiconductor-based system, apparatus, or device, or any suitable combination thereof. In general, for purposes of the present disclosure, a computer-readable and/or executable storage medium may be comprised of any tangible and/or non-transitory medium that is capable of containing and/or storing a program for use by or in connection with an instruction execution system, apparatus, processor, or device.

Similarly, for the purposes of the present disclosure, the term “component” may be comprised of any tangible, physical, and non-transitory device. For example, a component may be in the form of a hardware logic circuit that is comprised of customized VLSI circuits, gate arrays, or other integrated circuits, or is comprised of off-the-shelf semiconductors that include logic chips, transistors, or other discrete components, or any other suitable mechanical and/or electronic devices. In addition, a component could also be implemented in programmable hardware devices such as field programmable gate arrays (FPGA), programmable array logic, programmable logic devices, etc. Furthermore, a component may be comprised of one or more silicon-based integrated circuit devices, such as chips, die, die planes, and packages, or other discrete electrical devices, in an electrical communication configuration with one or more other components via electrical conductors of, for example, a printed circuit board (PCB) or the like. Accordingly, a module, as defined above, may in certain embodiments, be embodied by or implemented as a component and, in some instances, the terms module and component may be used interchangeably.

Where the term “circuit” is used herein, it includes one or more electrical and/or electronic components that constitute one or more conductive pathways that allow for electrical current to flow. A circuit may be in the form of a closed-loop configuration or an open-loop configuration. In a closed-loop configuration, the circuit components may provide a return pathway for the electrical current. By contrast, in an open-looped configuration, the circuit components therein may still be regarded as forming a circuit despite not including a return pathway for the electrical current. For example, an integrated circuit is referred to as a circuit irrespective of whether the integrated circuit is coupled to ground (as a return pathway for the electrical current) or not. In certain exemplary embodiments, a circuit may comprise a set of integrated circuits, a sole integrated circuit, or a portion of an integrated circuit. For example, a circuit may include customized VLSI circuits, gate arrays, logic circuits, and/or other forms of integrated circuits, as well as may include off-the-shelf semiconductors such as logic chips, transistors, or other discrete devices. In a further example, a circuit may comprise one or more silicon-based integrated circuit devices, such as chips, die, die planes, and packages, or other discrete electrical devices, in an electrical communication configuration with one or more other components via electrical conductors of, for example, a printed circuit board (PCB). A circuit could also be implemented as a synthesized circuit with respect to a programmable hardware device such as a field programmable gate array (FPGA), programmable array logic, and/or programmable logic devices, etc. In other exemplary embodiments, a circuit may comprise a network of non-integrated electrical and/or electronic components (with or without integrated circuit devices). Accordingly, a module, as defined above, may in certain embodiments, be embodied by or implemented as a circuit.

It will be appreciated that example embodiments that are disclosed herein may be comprised of one or more microprocessors and particular stored computer program instructions that control the one or more microprocessors to implement, in conjunction with certain non-processor circuits and other elements, some, most, or all of the functions disclosed herein. Alternatively, some or all functions could be implemented by a state machine that has no stored program instructions, or in one or more application-specific integrated circuits (ASICs) or field-programmable gate arrays (FPGAs), in which each function or some combinations of certain of the functions are implemented as custom logic. A combination of these approaches may also be used. Further, references below to a “controller” shall be defined as comprising individual circuit components, an application-specific integrated circuit (ASIC), a microcontroller with controlling software, a digital signal processor (DSP), a field programmable gate array (FPGA), and/or a processor with controlling software, or combinations thereof.

Additionally, the terms “couple,” “coupled,” or “couples,” where may be used herein, are intended to mean either a direct or an indirect connection. Thus, if a first device couples, or is coupled to, a second device, that connection may be by way of a direct connection or through an indirect connection via other devices (or components) and connections.

Regarding, the use herein of terms such as “an embodiment,” “one embodiment,” an “exemplary embodiment,” a “particular embodiment,” or other similar terminology, these terms are intended to indicate that a specific feature, structure, function, operation, or characteristic described in connection with the embodiment is found in at least one embodiment of the present disclosure. Therefore, the appearances of phrases such as “in one embodiment,” “in an embodiment,” “in an exemplary embodiment,” etc., may, but do not necessarily, all refer to the same embodiment, but rather, mean “one or more but not all embodiments” unless expressly specified otherwise. Further, the terms “comprising,” “having,” “including,” and variations thereof, are used in an open-ended manner and, therefore, should be interpreted to mean “including, but not limited to . . . ” unless expressly specified otherwise. Also, an element that is preceded by “comprises . . . a” does not, without more constraints, preclude the existence of additional identical elements in the subject process, method, system, article, or apparatus that includes the element.

The terms “a,” “an,” and “the” also refer to “one or more” unless expressly specified otherwise. By way of example, “a processor” programmed to perform various functions refers to one processor programmed to perform each and every function or more than one processor collectively programmed to perform each of the various functions. In addition, the phrase “at least one of A and B” as may be used herein and/or in the following claims, whereby A and B are variables indicating a particular object or attribute, indicates a choice of A or B, or both A and B, similar to the phrase “and/or.” Where more than two variables are present in such a phrase, this phrase is hereby defined as including only one of the variables, any one of the variables, any combination (or sub-combination) of any of the variables, and all of the variables.

Further, where used herein, the term “about” or “approximately” applies to all numeric values, whether or not explicitly indicated. These terms generally refer to a range of numeric values that one of skill in the art would consider equivalent to the recited values (e.g., having the same function or result). In certain instances, these terms may include numeric values that are rounded to the nearest significant figure.

In addition, any enumerated listing of items that is set forth herein does not imply that any or all of the items listed are mutually exclusive and/or mutually inclusive of one another, unless expressly specified otherwise. Further, the term “set,” as used herein, shall be interpreted to mean “one or more,” and in the case of “sets,” shall be interpreted to mean multiples of (or a plurality of) “one or more,” “ones or more,” and/or “ones or mores” according to set theory, unless expressly specified otherwise.

The foregoing detailed description has been presented for purposes of illustration and description. It is not intended to be exhaustive or be limited to the precise form disclosed. Many modifications and variations are possible in light of the above description. The described embodiments were chosen to best explain the principles of the technology and its practical application to thereby enable others skilled in the art to best utilize the technology in various embodiments and with various modifications as are suited to the particular use contemplated. The scope of the technology is defined by the claims appended hereto.

What is claimed is:

1. A memory apparatus, comprising:
memory cells each connected to one of a plurality of word lines and disposed in memory holes and configured to retain a threshold voltage corresponding to one of a plurality of data states; and
a control means configured to:
detect a valley point between distributions of the threshold voltage of two of the plurality of data states for a group of the memory cells in a threshold voltage tracking operation, and
determine whether the valley point is between a first identified one of the plurality of data states and a second identified one of the plurality of data states or between the second identified one of the plurality of data states and a third identified one of the plurality of data states and set an optimal read level for one of the plurality of data states based on a count of the memory cells associated with the valley point.

2. The memory apparatus as set forth in claim 1, wherein the control means is further configured to:
calculate a difference count equal to a difference between a first quantity of the memory cells of the group having the threshold voltage above a first threshold voltage stair sensing voltage associated with the valley point and a second quantity of the memory cells having the threshold voltage above a second threshold voltage stair sensing voltage associated with the valley point;
determine the valley point is between the first identified one of the plurality of data states and the second identified one of the plurality of data states and set a second identified optimal read level for the second identified one of the plurality of data states as the threshold voltage corresponding to the valley point in response to the difference count being less than a predetermined threshold count associated with the third identified one of the plurality of data states; and
determine the valley point is between a second identified one of the plurality of data states and the third identified one of the plurality of data states and set a third identified optimal read level for the third identified one of the plurality of data states as the threshold voltage corresponding to the valley point in response to the difference count not being less than the predetermined threshold count associated with the third identified one of the plurality of data states.

3. The memory apparatus as set forth in claim 2, wherein each of the memory cells is configured to store three bits, the plurality of data states include, in order of the threshold voltage increasing, an erase data state and a first programmed data state and a second programmed data state and a third programmed data state and a fourth programmed data state and a fifth programmed data state and a sixth programmed data state and a seventh programmed data state, and the first identified one of the plurality of data states is the fifth programmed data state and the second identified one of the plurality of data states is the sixth programmed data state and the third identified one of the plurality of data states is the seventh programmed data state.

4. The memory apparatus as set forth in claim 2, wherein the control means is further configured to continue scanning for another valley point between the second identified one of the plurality of data states and the third identified one of the plurality of data states in response to the difference count being less than a predetermined threshold count associated with the third identified one of the plurality of data states.

5. The memory apparatus as set forth in claim 1, wherein the control means is further configured to:
read the memory cells of the group at a predetermined read level associated with a second identified one and a third identified one of the plurality of data states and count a cell quantity of the memory cells of the group having the threshold voltage greater than the predetermined read level;
set a second identified optimal read level for the second identified one of the plurality of data states as the threshold voltage corresponding to the valley point in response to the cell quantity being approximately equal to a second predetermined expected amount of the memory cells for the second identified one of the plurality of data states; and
set a third identified optimal read level for the third identified one of the plurality of data states as the threshold voltage corresponding to the valley point in response to the cell quantity being approximately equal to a third predetermined expected amount of the memory cells for the third identified one of the plurality of data states.

6. The memory apparatus as set forth in claim 5, wherein the group of the memory cells comprises the memory cells connected to a predetermined quantity of the plurality of word lines.

7. The memory apparatus as set forth in claim 5, wherein each of the memory cells is configured to store three bits, the plurality of data states include, in order of the threshold voltage increasing, an erase data state and a first programmed data state and a second programmed data state and a third programmed data state and a fourth programmed data state and a fifth programmed data state and a sixth programmed data state and a seventh programmed data state, the first identified one of the plurality of data states is the fifth programmed data state and the second identified one of the plurality of data states is the sixth programmed data state and the third identified one of the plurality of data states is the seventh programmed data state, and the second predetermined expected amount of the memory cells is approximately equal to two eighths of a total quantity of the memory cells of the group and the third predetermined expected amount of the memory cells is approximately equal to one eighths of the total quantity of the memory cells of the group.

8. A controller in communication with a memory apparatus including memory cells each connected to one of a plurality of word lines and disposed in memory holes and configured to retain a threshold voltage corresponding to one of a plurality of data states, the controller configured to:
instruct the memory apparatus to detect a valley point between distributions of the threshold voltage of two of the plurality of data states for a group of the memory cells in a threshold voltage tracking operation; and
instruct the memory apparatus to determine whether the valley point is between a first identified one of the plurality of data states and a second identified one of the plurality of data states or between the second identified one of the plurality of data states and a third identified one of the plurality of data states and set an optimal read level for one of the plurality of data states based on a count of the memory cells associated with the valley point.

9. The controller as set forth in claim 8, wherein the controller is further configured to:
calculate a difference count equal to a difference between a first quantity of the memory cells of the group having the threshold voltage above a first threshold voltage stair sensing voltage associated with the valley point and a second quantity of the memory cells having the threshold voltage above a second threshold voltage stair sensing voltage associated with the valley point;
determine the valley point is between the first identified one of the plurality of data states and the second identified one of the plurality of data states and set a second identified optimal read level for the second identified one of the plurality of data states as the threshold voltage corresponding to the valley point in response to the difference count being less than a predetermined threshold count associated with the third identified one of the plurality of data states; and
determine the valley point is between a second identified one of the plurality of data states and the third identified one of the plurality of data states and set a third identified optimal read level for the third identified one of the plurality of data states as the threshold voltage corresponding to the valley point in response to the difference count not being less than the predetermined threshold count associated with the third identified one of the plurality of data states.

10. The controller as set forth in claim 9, wherein each of the memory cells is configured to store three bits, the plurality of data states include, in order of the threshold voltage increasing, an erase data state and a first programmed data state and a second programmed data state and a third programmed data state and a fourth programmed data state and a fifth programmed data state and a sixth programmed data state and a seventh programmed data state, and the first identified one of the plurality of data states is the fifth programmed data state and the second identified one of the plurality of data states is the sixth programmed data state and the third identified one of the plurality of data states is the seventh programmed data state.

11. The controller as set forth in claim 9, wherein the controller is further configured to instruct the memory apparatus to continue scanning for another valley point between the second identified one of the plurality of data states and the third identified one of the plurality of data states in response to the difference count being less than a predetermined threshold count associated with the third identified one of the plurality of data states.

12. The controller as set forth in claim 8, wherein the controller is further configured to:
instruct the memory apparatus to read the memory cells of the group at a predetermined read level associated with a second identified one a third identified one of the plurality of data states and count a cell quantity of the memory cells of the group having the threshold voltage greater than the predetermined read level;
set a second identified optimal read level for the second identified one of the plurality of data states as the threshold voltage corresponding to the valley point in response to the cell quantity being approximately equal to a second predetermined expected amount of the memory cells for the second identified one of the plurality of data states; and
set a third identified optimal read level for the third identified one of the plurality of data states as the threshold voltage corresponding to the valley point in response to the cell quantity being approximately equal to a third predetermined expected amount of the memory cells for the third identified one of the plurality of data states.

13. The controller as set forth in claim 12, wherein each of the memory cells is configured to store three bits, the plurality of data states include, in order of the threshold voltage increasing, an erase data state and a first programmed data state and a second programmed data state and a third programmed data state and a fourth programmed data state and a fifth programmed data state and a sixth programmed data state and a seventh programmed data state, the first identified one of the plurality of data states is the fifth programmed data state and the second identified one of the plurality of data states is the sixth programmed data state and the third identified one of the plurality of data states is the seventh programmed data state, and the second predetermined expected amount of the memory cells is approximately equal to two eighths of a total quantity of the memory cells of the group and the third predetermined expected amount of the memory cells is approximately equal to one eighths of the total quantity of the memory cells of the group.

14. A method of operating a memory apparatus including memory cells each connected to one of a plurality of word lines and disposed in memory holes and configured to retain a threshold voltage corresponding to one of a plurality of data states, the method comprising the steps of:
detecting a valley point between distributions of the threshold voltage of two of the plurality of data states for a group of the memory cells in a threshold voltage tracking operation; and
determining whether the valley point is between a first identified one of the plurality of data states and a second identified one of the plurality of data states or between the second identified one of the plurality of data states and a third identified one of the plurality of data states and setting an optimal read level for one of the plurality of data states based on a count of the memory cells associated with the valley point.

15. The method as set forth in claim 14, further including the steps of:
calculating a difference count equal to a difference between a first quantity of the memory cells of the group having the threshold voltage above a first threshold voltage stair sensing voltage associated with the valley point and a second quantity of the memory cells having the threshold voltage above a second threshold voltage stair sensing voltage associated with the valley point;
determining the valley point is between the first identified one of the plurality of data states and the second identified one of the plurality of data states and setting a second identified optimal read level for the second identified one of the plurality of data states as the threshold voltage corresponding to the valley point in response to the difference count being less than a predetermined threshold count associated with the third identified one of the plurality of data states; and
determining the valley point is between a second identified one of the plurality of data states and the third identified one of the plurality of data states and setting a third identified optimal read level for the third identified one of the plurality of data states as the threshold voltage corresponding to the valley point in response to the difference count not being less than the predetermined threshold count associated with the third identified one of the plurality of data states.

16. The method as set forth in claim 15, wherein each of the memory cells is configured to store three bits, the plurality of data states include, in order of the threshold voltage increasing, an erase data state and a first programmed data state and a second programmed data state and a third programmed data state and a fourth programmed data state and a fifth programmed data state and a sixth programmed data state and a seventh programmed data state, and the first identified one of the plurality of data states is the fifth programmed data state and the second identified one of the plurality of data states is the sixth programmed data state and the third identified one of the plurality of data states is the seventh programmed data state.

17. The method as set forth in claim 15, further including the step of continuing scanning for another valley point between the second identified one of the plurality of data states and the third identified one of the plurality of data states in response to the difference count being less than a predetermined threshold count associated with the third identified one of the plurality of data states.

18. The method as set forth in claim 14, further including the step of:
reading the memory cells of the group at a predetermined read level associated with a second identified one and a third identified one of the plurality of data states and counting a cell quantity of the memory cells of the group having the threshold voltage greater than the predetermined read level;
setting a second identified optimal read level for the second identified one of the plurality of data states as the threshold voltage corresponding to the valley point in response to the cell quantity being approximately equal to a second predetermined expected amount of the memory cells for the second identified one of the plurality of data states; and
setting a third identified optimal read level for the third identified one of the plurality of data states as the threshold voltage corresponding to the valley point in response to the cell quantity being approximately equal to a third predetermined expected amount of the memory cells for the third identified one of the plurality of data states.

19. The method as set forth in claim 18, wherein the group of the memory cells comprises the memory cells connected to a predetermined quantity of the plurality of word lines.

20. The method as set forth in claim 18, wherein each of the memory cells is configured to store three bits, the plurality of data states include, in order of the threshold voltage increasing, an erase data state and a first programmed data state and a second programmed data state and a third programmed data state and a fourth programmed data state and a fifth programmed data state and a sixth programmed data state and a seventh programmed data state, the first identified one of the plurality of data states is the fifth programmed data state and the second identified one of the plurality of data states is the sixth programmed data state and the third identified one of the plurality of data states is the seventh programmed data state, and the second predetermined expected amount of the memory cells is approximately equal to two eighths of a total quantity of the memory cells of the group and the third predetermined expected amount of the memory cells is approximately equal to one eighths of the total quantity of the memory cells of the group.
